(19) United States
(12) Patent Application Publication
(10) Pub. No.: US 2026/0047212 A1
(43) Pub. Date: Feb. 12, 2026

(54) SEMICONDUCTOR DEVICE AND METHOD FOR FABRICATING THE SAME

(71) Applicant: Samsung Electronics Co., Ltd., Suwon-si (KR)

(72) Inventors: Young Gwon KIM, Suwon-si (KR); Myung Gil KANG, Suwon-si (KR); Wook Hyun KWON, Suwon-si (KR); Guk Il AN, Suwon-si (KR); Kyung Hwan YANG, Suwon-si (KR); Yun Yeong YI, Suwon-si (KR); Byoung Hak HONG, Suwon-si (KR)

(21) Appl. No.: 19/286,330

(22) Filed: Jul. 31, 2025

(30) Foreign Application Priority Data
Aug. 7, 2024 (KR) 10-2024-0105188

(51) Int. Cl. H10D 89/60; H10D 8/00; H10D 30/00; H10D 30/01; H10D 62/10; H10D 62/13; H10D 64/23; H10D 84/01; H10D 84/80

(52) U.S. Cl. CPC H10D 89/611; H10D 8/411; H10D 30/502; H10D 62/103; H10D 62/116; H10D 62/151; H10D 64/256; H10D 84/811; H10D 30/0191; H10D 84/0107

(57) ABSTRACT

There is provided a semiconductor device with improved yield and performance. The semiconductor device includes a substrate including a first region and a second region and having a first conductivity type, first and second active patterns spaced apart by a first pitch, on the first region, a first gate structure intersecting the first and second active patterns, first epitaxial patterns each having a second conductivity type, different from the first conductivity type, and receiving the same voltage level, on both sides of the first gate structure on each of the first and second active patterns, third and fourth active patterns spaced apart by a second pitch, on the second region, a second gate structure intersecting the third and fourth active patterns, and second epitaxial patterns each having the second conductivity type, on the sides of the second gate structure on each of the third and fourth active patterns, wherein the first pitch is n times the second pitch (where n is a natural number of 2 or greater), and no epitaxial pattern having the second conductivity type is disposed between the first and second active patterns

### CROSS-REFERENCE TO RELATED APPLICATION

This application claims priority from Korean Patent Application No. 10-2024-0105188 filed on Aug. 7, 2024 in the Korean Intellectual Property Office, and all the benefits accruing therefrom under 35 U.S. C. 119, the contents of which in its entirety are herein incorporated by reference.

### BACKGROUND

### 1. Field

The present disclosure relates to a semiconductor device and a method for fabricating the same, and more particularly, to a semiconductor device including multi-bridge channels and a method for fabricating the semiconductor device.

### 2. Description of the Related Art

As one of the scaling technologies to increase the density of integrated circuit (IC) devices, multi-gate transistors have been proposed in which a fin- or nanowire-shaped silicon body is formed on a substrate and then gates are formed on the surface of the silicon body.

Since these multi-gate transistors utilize three-dimensional (3D) channels, scaling is easier. Moreover, current control capabilities can be enhanced without increasing the gate length of the multi-gate transistors. Additionally, a short channel effect (SCE), where the potential of a channel region is influenced by a drain voltage, can be effectively suppressed.

### SUMMARY

Aspects of the present disclosure provide a semiconductor device with improved yield and performance.

Aspects of the present disclosure also provide a method for fabricating a semiconductor device with improved yield and performance.

However, aspects of the present invention are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising a substrate including a first region and a second region and having a first conductivity type, first and second active patterns spaced apart from each other by a first pitch, on the first region, a first gate pattern intersecting the first and second active patterns, the first gate pattern having a first side and a second side facing away from each other, first epitaxial patterns each having a second conductivity type, different from the first conductivity type, on the first and second sides of the first gate pattern on each of the first and second active patterns, the first epitaxial patterns configured to receive the same voltage level as each other, third and fourth active patterns spaced apart from each other by a second pitch, on the second region, a second gate pattern intersecting the third and fourth active patterns, the second gate pattern having a third side and a fourth side facing away from each other, and second epitaxial patterns each having the second conductivity type, on the third and fourth sides of the second gate pattern on each of the third and fourth active patterns, wherein the first pitch is n times the second pitch (where n is a natural number of 2 or greater), and no epitaxial pattern having the second conductivity type is disposed between the first and second active patterns.

According to another aspect of the present disclosure, there is provided a semiconductor device comprising, a substrate having p-type conductivity, a plurality of active patterns extending parallel to each other on the substrate, a gate pattern intersecting the plurality of active patterns, the gate pattern having a first side and a second side facing away from each other, epitaxial patterns on the first and second sides of the gate pattern, the epitaxial patterns configured to receive the same voltage level as each other and having n-type conductivity, and insertion patterns each of which interposed between a corresponding one of the epitaxial patterns and the substrate, wherein a plurality of recesses is formed in each of the plurality of active patterns, each of the insertion patterns fills a portion of a corresponding one of the plurality of recesses, the plurality of active patterns include first to third active patterns that are sequentially arranged, the first and second active patterns are spaced apart from each other by a first pitch, the second and third active patterns are spaced apart from each other by a second pitch, the second pitch is n times greater than the first pitch, n is a natural number of 2 or greater, and no epitaxial pattern including n-type conductivity is disposed between the second and third active patterns.

According to still another aspect of the present disclosure, there is provided a semiconductor device comprising, a substrate having p-type conductivity, first to third active patterns on the substrate, the first to third active patterns each extending in a first direction and sequentially arranged along a second direction intersecting the first direction, a gate pattern extending in the second direction on the first to third active patterns, the gate pattern having a first side and a second side facing away from each other, first epitaxial patterns each connected to the substrate and each having n-type conductivity, on the first and second sides of the gate pattern on the first active pattern, second epitaxial patterns each connected to the substrate and each having p-type conductivity, on the first and second sides of the gate pattern on the second active pattern, and third epitaxial patterns each connected to the substrate and each having n-type conductivity, on the first and second sides of the gate pattern on the third active pattern, wherein each of the first to third active patterns includes a plurality of channel patterns that are stacked and spaced apart from each other on the substrate, and the first and third epitaxial patterns configured to receive the same voltage level as each other.

It should be noted that the effects of the present invention are not limited to those described above, and other effects of the present disclosure may be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout view for explaining a semiconductor device according to some embodiments.

FIG. 2 is a cross-sectional view taken along line A1-A1 of FIG. 1.

FIG. 3 is a cross-sectional view taken along line A2-A2 of FIG. 1.

FIG. 4 illustrates enlarged cross-sectional views for explaining a region R1 of FIG. 2 and a region R2 of FIG. 3.

FIG. 5 is a cross-sectional view taken along line B-B of FIG. 1.

FIG. 6 is a cross-sectional view taken along line C-C of FIG. 1.

FIG. 7 is an example layout view for explaining a semiconductor device according to some embodiments.

FIG. 8 is a cross-sectional view taken along line D-D of FIG. 7.

FIG. 9 is an example layout view for explaining a semiconductor device according to some embodiments.

FIG. 10 is a cross-sectional view taken along line E-E of FIG. 9.

FIG. 11 is an example layout view for explaining a semiconductor device according to some embodiments.

FIG. 12 is a cross-sectional view taken along line F-F of FIG. 11.

FIG. 13 is an example layout view for explaining a semiconductor device according to some embodiments.

Each of FIGS. 14 through 35 is either an example layout view or a cross-sectional view illustrating a method for manufacturing a semiconductor device according to some embodiments.

### DETAILED DESCRIPTION

It may be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present invention. For example, terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise. For example, “same” means not only completely identical but also includes slight differences that may occur due to process margins, etc.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

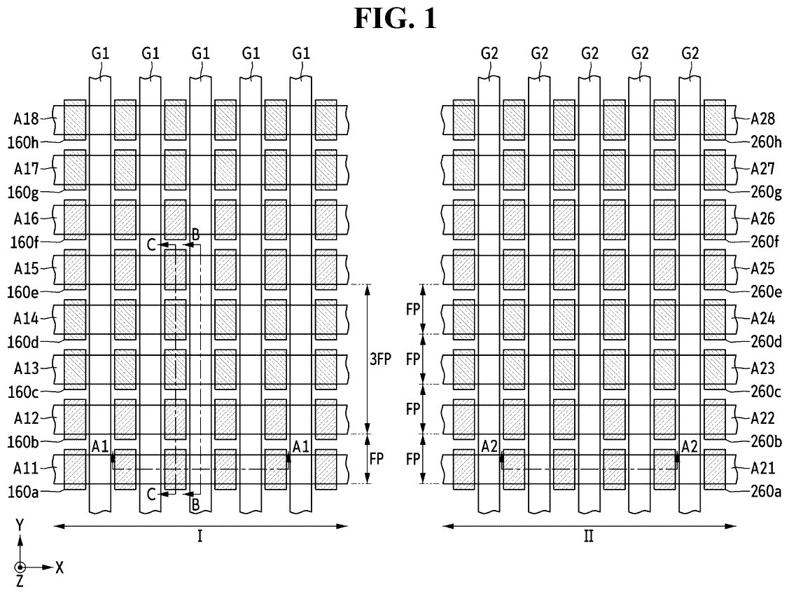

Embodiments of the present disclosure will be described with reference to FIGS. 1 through 13.

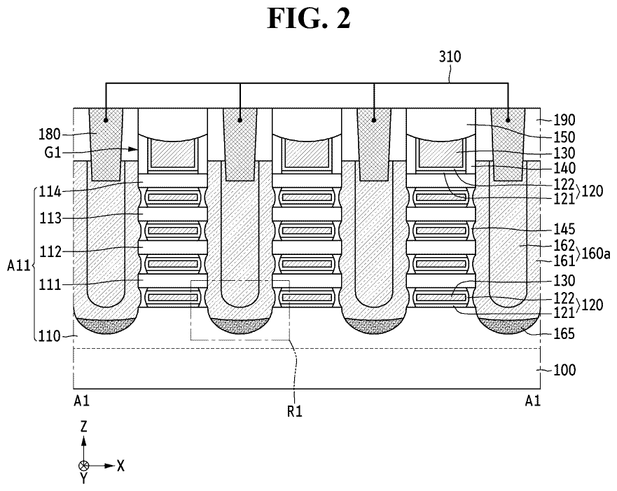

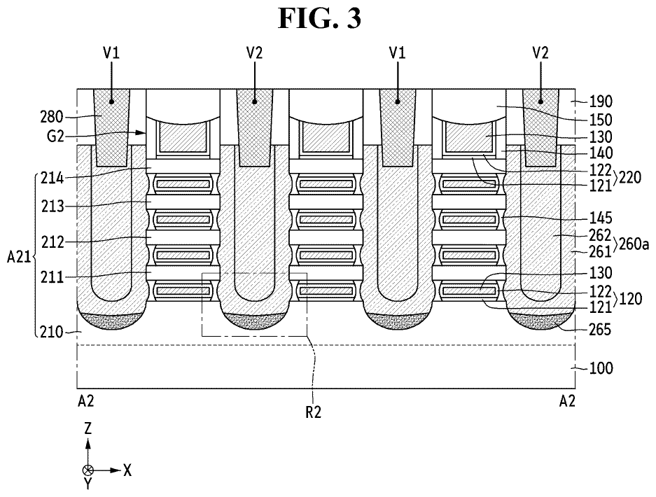

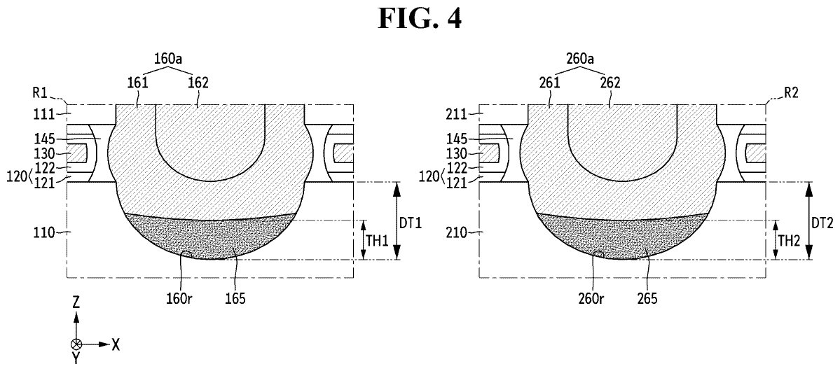

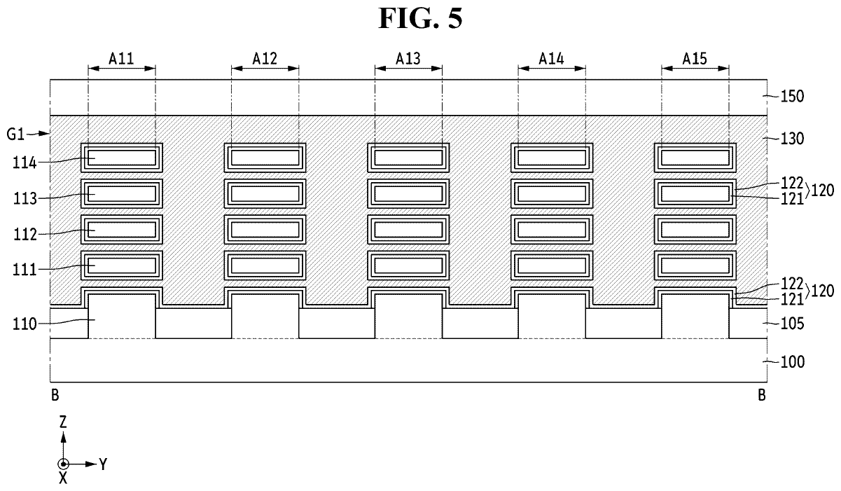

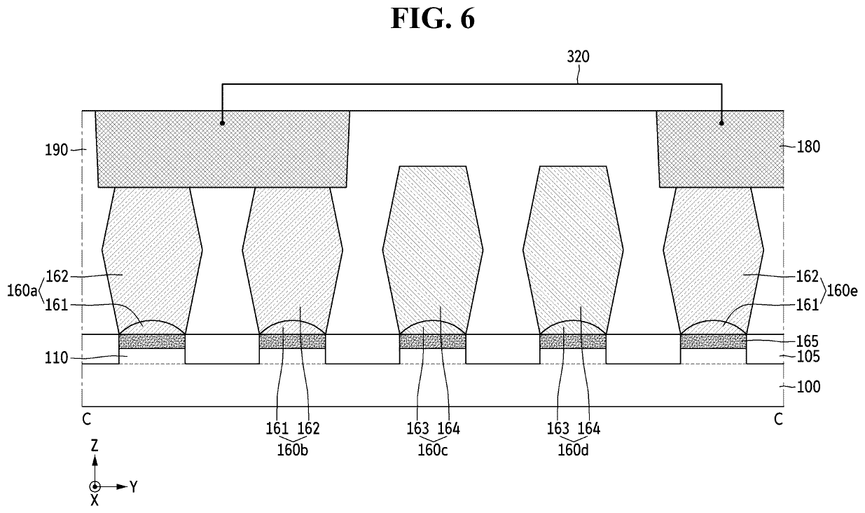

FIG. 1 is an example layout view for explaining a semiconductor device according to some embodiments. FIG. 2 is a cross-sectional view taken along line A1-A1 of FIG. 1. FIG. 3 is a cross-sectional view taken along line A2-A2 of FIG. 1. FIG. 4 illustrates enlarged cross-sectional views for explaining a region R1 of FIG. 2 and a region R2 of FIG. 3. FIG. 5 is a cross-sectional view taken along line B-B of FIG. 1. FIG. 6 is a cross-sectional view taken along line C-C of FIG. 1.

Referring to FIGS. 1 through 6, the semiconductor device according to some embodiments may include a substrate 100, first through eighth active patterns A11 through A18, ninth through sixteenth active patterns A21 through A28, a field insulating film 105, first gate structures G1, second gate structures G2, first through eighth epitaxial patterns 160a through 160h, a first insertion film (first insertion patterns) 165, ninth through sixteenth epitaxial patterns 260a through 260h, a second insertion film (second insertion patterns) 265, an interlayer insulating film 190, first source/drain contacts 180, and second source/drain contacts 280.

The substrate 100 may be a bulk silicon (Si) or Si-on-insulator (SOI) substrate. Alternatively, the substrate 100 may be an Si substrate or may include other materials, for example, silicon-germanium (SiGe), SiGe-on-insulator (SGOI), indium antimonide, a lead telluride compound, indium arsenide, indium phosphide, gallium arsenide, or gallium antimonide. Alternatively, the substrate 100 may have an epitaxial layer formed on a base substrate. The substrate 100 will hereinafter be described as being, for example, an Si substrate.

The substrate 100 may include a first region I and a second region II. The first and second regions I and II may be connected to each other or may be separate from each other.

The substrate 100 may have a first conductivity type. For example, the substrate 100 may include p-type impurities (charge carrier dopants) such as B, In, Ga, or Al. The first and second conductivity types will hereinafter be described as being, for example, p-type and n-type conductivity, respectively, but the present invention is not limited thereto. Alternatively, the first conductivity type may be n-type.

In semiconductor technology, if a semiconductor contains both p-type and n-type impurities, the conductivity-type of the semiconductor may be determined by which type of impurity is in greater concentration. Therefore, if a semiconductor has both p-type and n-type impurities, the net conductivity type may be determined by the dominant impurity concentration. As used herein, a semiconductor region of (or having) a “first conductivity-type” denotes that the dominant impurities in the semiconductor region is (or are) a first conductivity-type impurity, and a “concentration of the first conductivity-type” in the semiconductor region (or a “impurity concentration”) refers the net concentration of the impurities in the semiconductor region (i.e., (the amount of first conductivity-type impurities minus the amount of second conductivity-type impurities)/the volume of the semiconductor region).

The first through eighth active patterns A11 through A18 may be formed on the first region I of the substrate 100. The first through eighth active patterns A11 through A18 may extend parallel to each other. For example, the first through eighth active patterns A11 through A18 may extend in a first direction X that is parallel to the upper surface of the substrate 100, and may be sequentially arranged in a second direction Y that is parallel to the upper surface of the substrate 100 and intersects the first direction X.

The first through eighth active patterns A11 through A18 may be arranged at the same pitch. Here, the term “pitch” refers to the sum of the gap between a pair of adjacent active patterns and the width of one of the pair of adjacent active patterns, or the distance between the center of one active pattern and the center of an adjacent active pattern. For example, as illustrated in FIG. 1, a first pitch FP between the first and second active patterns A11 and A12 may be defined as the sum of the gap between the first and second active patterns A11 and A12 and the width of the first active pattern A11. Each adjacent pair of the first through eighth active patterns A11 through A18 may be spaced apart from each other by the first pitch FP.

Each of the first through eighth active patterns A11 through A18 may include a plurality of first bridge patterns (111 through 114) that are stacked on the substrate 100 and spaced apart from each other. The first bridge patterns (111 through 114) may extend in the first direction X and may be spaced apart from each other in a third direction Z intersecting the upper surface of the substrate 100. In some embodiments, the first bridge patterns (111 through 114) may be used as the channel regions of Multi-Bridge Channel Field-Effect Transistors (MBCFETs®) that include multi-bridge channels on the first region I. The number, shape, and arrangement of the first bridge patterns (111 through 114) are merely examples, and the invention is not limited thereto.

In some embodiments, each of the first through eighth active patterns A11 through A18 may further include a first fin pattern 110 protruding from the upper surface of the substrate 100. The first fin pattern 110 may extend in the first direction X. The first bridge patterns (111 through 114) may be spaced apart from the first fin pattern 110 in the third direction Z. The first fin pattern 110 may be formed by etching a portion of the substrate 100 or may be an epitaxial layer grown from the substrate 100 such that the first fin pattern 110 is formed integrally with the substrate 100. For example, the first fin pattern 110 and the substrate 100 may be a continuous structure formed of the same material without a boundary interface therebetween.

The ninth through sixteenth active patterns A21 through A28 may be formed on the second region II of the substrate 100. The ninth through sixteenth active patterns A21 through A28 may extend parallel to each other. For example, the ninth through sixteenth active patterns A21 through A28 may extend in the first direction X and may be sequentially arranged in the second direction Y. The ninth through sixteenth active patterns A21 through A28 may extend parallel to the first through eighth active patterns A11 through A18, but the present invention is not limited thereto. Alternatively, in some embodiments, contrary to what is illustrated in the drawings, the ninth through sixteenth active patterns A21 through A28 may extend in a direction different from the first through eighth active patterns A11 through A18.

The ninth through sixteenth active patterns A21 through A28 may be arranged at the same pitch as the first through eighth active patterns A11 through A18. For example, as illustrated in FIG. 1, each adjacent pair of the ninth through sixteenth active patterns A21 through A28 may be spaced apart from each other by the same pitch as the first through eighth active patterns A11 through A18, i.e., the first pitch FP.

Each of the ninth through sixteenth active patterns A21 through A28 may include a plurality of second bridge patterns (211 through 214) that are stacked on the substrate 100 and spaced apart from each other. The second bridge patterns (211 through 214) may extend in the first direction X and may be spaced apart from each other in the third direction Z. The second bridge patterns (211 through 214) may be used as the channel regions of MBCFETs® that include multi-bridge channels on the second region II. The number, shape, and arrangement of the second bridge patterns (211 through 214) are merely examples, and the invention is not limited thereto. The first bridge patterns and second bridge patterns may be first channel patterns and second channel patterns, respectively.

In some embodiments, each of the ninth through sixteenth active patterns A21 through A28 may further include a second fin pattern 210 protruding from the upper surface of the substrate 100. The second fin pattern 210 may extend in the first direction X. The second bridge patterns (211 through 214) may be spaced apart from the second fin pattern 210 in the third direction Z. The second fin pattern 210 may be formed by etching a portion of the substrate 100 or may be an epitaxial layer grown from the substrate 100 such that second fin pattern 210 is formed integrally with the substrate 100.

The first through eighth active patterns A11 through A18 and the ninth through sixteenth active patterns A21 through A28 may each include an elemental semiconductor material such as Si or germanium (Ge). Alternatively, the first through eighth active patterns A11 through A18 and the ninth through sixteenth active patterns A21 through A28 may each include a compound semiconductor, for example, a Group IV-IV compound semiconductor or a Group III-V compound semiconductor. The Group IV-IV compound semiconductor may include, for example, a binary or ternary compound containing at least two of carbon (C), Si, Ge, and tin (Sn), or a compound obtained by doping the binary or ternary compound with a Group IV element. The Group III-V compound semiconductor may include, for example, a binary, ternary, or quaternary compound obtained by combining at least one Group III element such as aluminum (Al), gallium (Ga), or indium (In) with at least one Group V element such as phosphorus (P), arsenic (As), or antimony (Sb). The first through eighth active patterns A11 through A18 and the ninth through sixteenth active patterns A21 through A28 may hereinafter be described as being, for example, Si patterns, which include the first and second bridge patterns (111 through 114 and 211 through 214).

The field insulating film 105 may be formed on the substrate 100. The field insulating film 105 may separate the first through eighth active patterns A11 through A18 and the ninth through sixteenth active patterns A21 through A28. In some embodiments, the field insulating film 105 may cover at least portions of the sides of the first fin pattern 110 and at least portions of the sides of the second fin pattern 210.

The field insulating film 105 may include, for example, at least one of silicon oxide, silicon nitride, silicon oxynitride, or a combination thereof, but the present invention is not limited thereto. For example, the field insulating film 105 may include a silicon oxide film.

The first gate structures G1 may be formed on the first region I of the substrate 100 and the field insulating film 105. The first gate structures G1 may intersect the first through eighth active patterns A11 through A18. For example, the first gate structures G1 may extend in the second direction Y. The first bridge patterns (111 through 114) may extend in the first direction X and may penetrate the first gate structures G1. For example, the first gate structures G1 may surround the periphery of each of the first bridge patterns (111 through 114). A plurality of first gate structures G1 may be arranged along the first direction X to be spaced apart from each other.

The second gate structures G2 may be formed on the second region II of the substrate 100 and the field insulating film 105. The second gate structures G2 may intersect the ninth through sixteenth active patterns A21 through A28. For example, the second gate structures G2 may extend in the second direction Y. The second bridge patterns (211 through 214) may extend in the first direction X and may penetrate the second gate structures G2. For example, the second gate structures G2 may surround the periphery of each of the second bridge patterns (211 through 214). A plurality of second gate structures G2 may be arranged along the first direction X to be spaced apart from one another.

In some embodiments, the first gate structures G1 and the second gate structures G2 may include a gate dielectric film 120, gate electrodes 130, gate spacers 140 and 145, and a gate capping film 150. The first gate structures G1 and second gate structures G2 may be a first gate pattern and a second gate pattern, respectively.

The gate dielectric film 120 may be formed on the first through eighth active patterns A11 through A18 and the ninth through sixteenth active patterns A21 through A28. The gate dielectric film 120 may be interposed between the first through eighth active patterns A11 through A18 and the gate electrodes 130 and between the ninth through sixteenth active patterns A21 through A28 and the gate electrodes 130. In some embodiments, the gate dielectric film 120 may further extend along and/or on the first fin pattern 110, the second fin pattern 210, and the field insulating film 105.

The gate dielectric film 120 may include a dielectric material, for example, at least one of silicon oxide, silicon oxynitride, silicon nitride, or a high-k dielectric material with a higher dielectric constant than silicon oxide. The high-k dielectric material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanate, barium titanate, strontium titanate, yttrium oxide, aluminum oxide, lead scandium tantalum oxide, lead zinc niobate, or a combination thereof, but the present invention is not limited thereto.

In some embodiments, the gate dielectric film 120 may include an interfacial film 121 and a high-k dielectric film 122 that are sequentially stacked on the first through eighth active patterns A11 through A18 and the ninth through sixteenth active patterns A21 through A28.

The interfacial film 121 may conformally extend along the periphery of each of the first bridge patterns (111 through 114) and the periphery of each of the second bridge patterns (211 through 214). The interfacial film 121 may include, for example, at least one of silicon oxide, silicon oxynitride, or silicon nitride. In some embodiments, the interfacial film 121 may include an oxide of the material included in the first bridge patterns (111 through 114) and/or the second bridge patterns (211 through 214). For instance, the interfacial film 121 may include a silicon oxide film.

The high-k dielectric film 122 may conformally extend along the interfacial film 121. A portion of the high-k dielectric film 122 may conformally extend along the periphery of the interfacial film 121. The high-k dielectric film 122 may include, for example, the aforementioned high-k dielectric material.

The gate electrodes 130 may be stacked on the gate dielectric film 120. The gate electrodes 130 may include a conductive material such as TiN, WN, TaN, Ru, TiC, TaC, Ti, Ag, Al, TiAl, TiAlN, TiAlC, TaCN, TaSiN, Mn, Zr, W, or a combination thereof, but the present invention is not limited thereto.

The gate electrodes 130 are illustrated as being single films, but the present invention is not limited thereto. Alternatively, the gate electrodes 130 may be formed by stacking multiple conductive films. For example, the gate electrodes 130 may each include a work function adjustment film and a filling conductive film that fills the space formed by the work function adjustment layer. The work function adjustment film may include, for example, at least one of TiN, TaN, TiC, TaC, TiAlC, or a combination thereof. The filling conductive film may include, for example, W or Al.

The gate spacers 140 and 145 may extend along the sides of the gate electrodes 130. The first bridge patterns (111 through 114) and the second bridge patterns (211 through 214) may extend in the first direction X and penetrate the gate spacers 140 and 145. The gate spacers 140 and 145 may include an insulating material, for example, at least one of silicon oxide, silicon nitride, silicon oxynitride, silicon oxycarbide, silicon boron nitride, silicon carbon boron nitride, silicon oxycarbonitride, or a combination thereof, but the present invention is not limited thereto. The gate spacers 140 may be upper gate spacers, and the gate spacers 145 may be inner gate spacers.

In some embodiments, portions of the gate dielectric film 120 may be interposed between the gate electrodes 130 and the gate spacers 140 and 145. For example, portions of the high-k dielectric film 122 may further extend along the inner sides of the gate spacers 140 and 145.

The gate capping film 150 may extend along the upper surfaces of the gate electrodes 130. The gate capping film 150 may include an insulating material, for example, at least one of silicon oxide, silicon nitride, silicon oxynitride, silicon oxycarbide, silicon boron nitride, silicon carbon boron nitride, silicon oxycarbonitride, or a combination thereof, but the present invention is not limited thereto.

In some embodiments, the first gate patterns G1 and the second gate patterns G2 may each further include inner spacers 145. The inner spacers 145 may be formed on the sides of the gate electrodes 130 between the first bridge patterns (111 through 114) and on the sides of the gate electrodes 130 between the second bridge patterns (211 through 214). Additionally, the inner spacers 145 may also be formed on the sides of the gate electrodes 130 between the first fin pattern 110 and the first bridge patterns (111 through 114) and on the sides of the gate electrodes 130 and between the second fin pattern 210 and the second bridge patterns (211 through 214).

In some embodiments, portions of the gate dielectric film 120 may be interposed between the gate electrodes 130 and the inner spacers 145. For example, portions of the high-k dielectric film 122 may further extend along the inner sides of the inner spacers 145.

The first epitaxial patterns 160a through the eighth epitaxial patterns 160h may be arranged on both sides of the first gate structures G1. The first epitaxial patterns 160a through the eighth epitaxial patterns 160h may be formed on the first through eighth active patterns A11 through A18, respectively. The first epitaxial patterns 160a through the eighth epitaxial patterns 160h may be connected to the first through eighth active patterns A11 through A18, respectively. For example, the first bridge patterns (111 through 114) may penetrate the first gate structures G1 to be connected to the first epitaxial patterns 160a through the eighth epitaxial patterns 160h. The first epitaxial patterns 160a through the eighth epitaxial patterns 160h may be separate from the gate electrodes 130 by the gate dielectric film 120 and/or at least a set of the gate spacers 140 and 145.

The first epitaxial patterns 160a through the eighth epitaxial patterns 160h may each include an epitaxial layer doped with impurities. For example, the first epitaxial patterns 160a through the eighth epitaxial patterns 160h may be epitaxial layers grown by epitaxial growth from the first through eighth active patterns A11 through A18, respectively.

As illustrated in FIG. 6, in a cross-sectional view intersecting the first direction X, the first epitaxial patterns 160a through the eighth epitaxial patterns 160h are illustrated as having a hexagonal shape, but the present invention is not limited thereto. Alternatively, the first epitaxial patterns 160a through the eighth epitaxial patterns 160h may have various other cross-sectional shapes such as pentagonal, diamond, etc.

In some embodiments, the substrate 100 may include first recesses 160r on both sides of the first gate structures G1. For example, as illustrated in FIG. 4, the first recesses 160r may be formed in the upper surface of the first fin pattern 110 such that the upper surface has a concave shape. The first epitaxial patterns 160a through the eighth epitaxial patterns 160h may be formed in the first recesses 160r.

In some embodiments, the first epitaxial patterns 160a, the second epitaxial patterns 160b, the fifth epitaxial patterns 160e, and the sixth epitaxial patterns 160f may have a second conductivity type (e.g., n-type) different from the first conductivity type. For example, the first epitaxial patterns 160a, the second epitaxial patterns 160b, the fifth epitaxial patterns 160e, and the sixth epitaxial patterns 160f may include n-type impurities (e.g., P, Sb, or As) and/or impurities to prevent the diffusion of n-type impurities. In some embodiments, the first, second, fifth, and sixth active patterns A11, A12, A15, and A16 may be provided as the channel regions of n-type field-effect transistors (NFETs).

In some embodiments, the first epitaxial patterns 160a, the second epitaxial patterns 160b, the fifth epitaxial patterns 160e, and the sixth epitaxial patterns 160f may each include a first epitaxial film 161 and a second epitaxial film 162 that are sequentially stacked on the first fin pattern 110. The first epitaxial film 161 may extend along the upper surface of the first fin pattern 110 and the sides of the first bridge patterns (111 through 114). The first epitaxial film 161 may serve as a seed layer for growing the second epitaxial film 162. The impurity concentration of the second conductivity-type in the second epitaxial film 162 may be higher than the impurity concentration of the second conductivity-type in the first epitaxial film 161. For example, the n-type impurity concentration of the second epitaxial film 162 may be higher than the n-type impurity concentration of the first epitaxial film 161.

In some embodiments, the third epitaxial patterns 160c, the fourth epitaxial patterns 160d, the seventh epitaxial patterns 160g, and the eighth epitaxial patterns 160h may have the first conductivity type (e.g., p-type). For example, the third epitaxial patterns 160c, the fourth epitaxial patterns 160d, the seventh epitaxial patterns 160g, and the eighth epitaxial patterns 160h may include p-type impurities (e.g., B, In, Ga, or Al) and/or impurities to prevent the diffusion of p-type impurities. In some embodiments, the third epitaxial patterns 160c, the fourth epitaxial patterns 160d, the seventh epitaxial patterns 160g, and the eighth epitaxial patterns 160h may be provided as the channel regions of p-type field-effect transistors (PFETs).

In some embodiments, the third epitaxial patterns 160c, the fourth epitaxial patterns 160d, the seventh epitaxial patterns 160g, and the eighth epitaxial patterns 160h may each include a third epitaxial layer 163 and a fourth epitaxial layer 164 that are sequentially stacked on the first fin pattern 110. The third epitaxial layer 163 may extend along the upper surface of the first fin pattern 110 and the sides of the second bridge patterns (211 through 214). The third epitaxial layer 163 may serve as a seed layer for growing the fourth epitaxial layer 164. The impurity concentration of the first conductivity-type in the fourth epitaxial layer 164 may be higher than the impurity concentration of the first conductivity-type in the third epitaxial layer 163. For example, the p-type impurity concentration of the fourth epitaxial layer 164 may be higher than the p-type impurity concentration of the third epitaxial layer 163.

The first insertion film 165 may be formed between the substrate 100 and the first epitaxial patterns 160a through the eighth epitaxial patterns 160h. As illustrated in FIG. 4, the first insertion film 165 may fill portions of the first recesses 160r. The first epitaxial patterns 160a through the eighth epitaxial patterns 160h may be stacked on the first insertion film 165. The first epitaxial patterns 160a through the eighth epitaxial patterns 160h may fill the first recesses 160r that remain unfilled after the formation of the first insertion film 165.

In some embodiments, the first insertion film 165 may include a semiconductor film doped with impurities of the first conductivity type, an insulating film, and/or an undoped semiconductor film. For example, the first insertion film 165 may include at least one of an SiB film, an SiN film, or an undoped Si film.

In some embodiments, the upper surface of the first insertion film 165 may include an upwardly concave surface. The first epitaxial patterns 160a through the eighth epitaxial patterns 160h may each be in direct contact with the concave surface of the first insertion film 165.

The ninth epitaxial patterns 260a through the sixteenth epitaxial patterns 260h may be arranged on both sides of the second gate structures G2. The ninth epitaxial patterns 260a through the sixteenth epitaxial patterns 260h may be formed on the ninth through sixteenth active patterns A21 through A28, respectively. The ninth epitaxial patterns 260a through the sixteenth epitaxial patterns 260h may be connected to the ninth through sixteenth active patterns A21 through A28, respectively. For example, the second bridge patterns (211 through 214) may pass through the second gate structure G2 to be connected to the ninth epitaxial patterns 260a through the sixteenth epitaxial patterns 260h. The ninth epitaxial patterns 260a through the sixteenth epitaxial patterns 260h may be separate from the gate electrodes 130 by the gate dielectric film 120 and/or at least a set of the gate spacers 140 and 145.

The ninth epitaxial patterns 260a through the sixteenth epitaxial patterns 260h may each include an epitaxial layer doped with impurities. For example, the ninth epitaxial patterns 260a through the sixteenth epitaxial patterns 260h may be epitaxial layers grown by epitaxial growth from the ninth through sixteenth active patterns A21 through A28, respectively. The ninth epitaxial patterns 260a through the sixteenth epitaxial patterns 260h may be similar to the first epitaxial patterns 160a through the eighth epitaxial patterns 160h, and thus, detailed descriptions thereof may be omitted.

In some embodiments, the substrate 100 may include second recesses 260r on both sides of the second gate structures G2. For example, as illustrated in FIG. 4, the second recesses 260r may be formed in the upper surface of the second fin pattern 210 such that the upper surface has a concave shape. The ninth epitaxial patterns 260a through the sixteenth epitaxial patterns 260h may be formed in the second recesses 260r.

Each of the first and second recesses 160r and 260r may be formed in the upper surfaces of a corresponding one of active patterns A11 through A18 and A21 through A28.

In some embodiments, a first depth DT1 of the first recesses 160r may be formed to be the same as or similar to a second depth DT2 of the second recesses 260r. Here, the first depth DT1 may be defined as a maximum depth from the upper surface of the substrate 100 (or the upper surface of the first fin pattern 110), and the second depth DT2 may be defined as a maximum depth from the upper surface of the substrate 100 (or the upper surface of the second fin pattern 210). For example, the difference between the first and second depths DT1 and DT2 may be less than about 10%, or less than about 5%, or less than about 1%, based on the second depth DT2. For example, a difference between a selected one of the first depth DT1 and a selected one of the second depth DT2 may be 10% or less with respect to the selected one of the second depth DT2.

In some embodiments, the first depth DT1 may be about 60 nm to about 75 nm, or about 65 nm to about 75 nm, or about 66 nm to about 72 nm. Within this range, under-etching defects of the first through eighth active patterns A11 through A18 may be effectively prevented, and the leakage current generated from the lower portions of the first recesses 160r may be effectively reduced. For example, each of the first recesses 160r may be formed in the upper surface of a corresponding one of the active patterns A11 through A18, and a maximum depth of each of the recesses may be 60 nm to 75 nm from the upper surface of a corresponding one of the active patterns.

In some embodiments, the ninth epitaxial patterns 260a, the tenth epitaxial patterns 260b, the thirteenth epitaxial patterns 260e, and the fourteenth epitaxial patterns 260f may have the second conductivity type. For example, the ninth epitaxial patterns 260a, the tenth epitaxial patterns 260b, the thirteenth epitaxial patterns 260e, and the fourteenth epitaxial patterns 260f may include n-type impurities (e.g., P, Sb, or As) and/or impurities to prevent the diffusion of n-type impurities. Accordingly, the ninth, tenth, thirteenth, and fourteenth active patterns A21, A22, A25, and A26 may be provided as the channel regions of NFETs.

In some embodiments, the ninth epitaxial patterns 260a, the tenth epitaxial patterns 260b, the thirteenth epitaxial patterns 260e, and the fourteenth epitaxial patterns 260f may each include a fifth epitaxial layer 261 and a sixth epitaxial layer 262 that are sequentially stacked on the second fin pattern 210. The fifth epitaxial layer 261 may extend along the upper surface of the second fin pattern 210 and the sides of the second bridge patterns (211 through 214). The fifth epitaxial layer 261 may serve as a seed layer for growing the sixth epitaxial layer 262. The impurity concentration of the second conductivity-type in the sixth epitaxial layer 262 may be higher than the impurity concentration of the second conductivity-type in the fifth epitaxial layer 261. For example, the n-type impurity concentration of the sixth epitaxial layer 262 may be higher than the n-type impurity concentration of the fifth epitaxial layer 261.

In some embodiments, the eleventh epitaxial patterns 260c, the twelfth epitaxial patterns 260d, the fifteenth epitaxial patterns 260g, and the sixteenth epitaxial patterns 260h may have the first conductivity type. For example, the eleventh epitaxial patterns 260c, the twelfth epitaxial patterns 260d, the fifteenth epitaxial patterns 260g, and the sixteenth epitaxial patterns 260h may include p-type impurities (e.g., B, In, Ga, or Al) and/or impurities to prevent the diffusion of p-type impurities. Accordingly, the eleventh, twelfth, fifteenth, and sixteenth active patterns A23, A24, A27, and A28 may be provided as the channel regions of PFETs.

The second insertion film 265 may be formed between the substrate 100 and the ninth epitaxial patterns 260a through the sixteenth epitaxial patterns 260h. As illustrated in FIG. 4, the second insertion film 265 may fill portions of the second recesses 260r. The ninth epitaxial patterns 260a through the sixteenth epitaxial patterns 260h may be stacked on the second insertion film 265. The ninth epitaxial patterns 260a through the sixteenth epitaxial patterns 260h may fill portions of the second recesses 260r that remain unfilled after the formation of the second insertion film 265.

In some embodiments, the second insertion film 265 may include a semiconductor film doped with impurities of the first conductivity type, an insulating film, and/or an undoped semiconductor film. For example, the second insertion film 265 may include at least one of an SiB film, an SiN film, or an undoped Si film.

In some embodiments, the upper surface of the second insertion film 265 may include an upwardly concave surface. The ninth epitaxial patterns 260a through the sixteenth epitaxial patterns 260h may each be in direct contact with the concave surface of the second insertion film 265.

In some embodiments, a first thickness TH1 of the first insertion film 165 may be formed to be the same as or similar to a second thickness TH2 of the second insertion film 265. Here, the first thickness TH1 may be defined as the maximum thickness of the first insertion film 165, and the second thickness TH2 may be defined as the maximum thickness of the second insertion film 265. For example, the difference between the first and second thicknesses TH1 and TH2, based on the second thickness TH2, may be less than about 10%, or less than about 5%, or less than about 1%.

In some embodiments, the first thickness TH1 may be about 1 nm to about 10 nm, or about 3 nm to about 7 nm. For example, a maximum thickness of a selected one of the insertion patterns may be 1 nm to 10 nm in a direction perpendicular to the upper surface of the substrate. Within this range, the leakage current generated between the substrate 100 and the first epitaxial patterns 160a through the eighth epitaxial patterns 160h may be effectively reduced, and the leakage current generated from the lower portions of the first recesses 160r may also be effectively reduced.

The interlayer insulating film 190 may be formed on the substrate 100 and the field insulating film 105. The interlayer insulating film 190 may be formed to fill the spaces on the outer sides of the first gate structures G1 and the second gate structures G2. The interlayer insulating film 190 may cover the first epitaxial patterns 160a through the eighth epitaxial patterns 160h and the ninth epitaxial patterns 260a through the sixteenth epitaxial patterns 260h. The interlayer insulating film 190 is illustrated as exposing the upper surface of the gate capping film 150, but the present invention is not limited thereto. Alternatively, the interlayer insulating film 190 may cover the upper surface of the gate capping film 150.

The interlayer insulating film 190 may include, for example, at least one of silicon oxide, silicon nitride, silicon oxynitride, silicon oxycarbide, silicon boron nitride, silicon carbon boron nitride, silicon oxycarbonitride, or a low-k dielectric material with a lower dielectric constant than silicon oxide. The low-k dielectric material may include, for example, at least one of Flowable Oxide (FOX), Torene SilaZene (TOSZ), Undoped Silica Glass (USG), Borosilicate Glass (BSG), Phosphosilicate Glass (PSG), BoroPhosphosilicate Glass (BPSG), Plasma Enhanced Tetraethyl Orthosilicate (PETEOS), Fluorinated Silicate Glass (FSG), Carbon Doped Silicon Oxide (CDO), Xerogel, Aerogel, Amorphous Fluorinated Carbon, Organosilicate Glass (OSG), Parylene, bis-benzocyclobutene (BCB), SiLK, polyimide, a porous polymeric material, or a combination thereof, but the present invention is not limited thereto.

The first source/drain contacts 180 may be electrically connected to at least some of the first epitaxial patterns 160a through eighth epitaxial patterns 160h. For example, the first source/drain contacts 180 may contact the upper portions of at least some of the first epitaxial patterns 160a through eighth epitaxial patterns 160h through the interlayer insulating film 190.

In some embodiments, each of the first epitaxial patterns 160a through eighth epitaxial patterns 160h may be configured to have the same potential on both sides of the first gate structures G1. For example, as illustrated in FIG. 2, first epitaxial patterns 160a disposed at both sides of the first gate structures G1 may be electrically connected to one another through first wires 310. As a result, the same voltage level may be applied to the first epitaxial patterns 160a disposed at both sides of the first gate structures G1. Though not shown in the drawings, the first wires 310 may be formed to extend in the first direction X.

In some embodiments, n-type epitaxial patterns among the first epitaxial patterns 160a through eighth epitaxial patterns 160h, for example, the first epitaxial patterns 160a, the second epitaxial patterns 160b, the fifth epitaxial patterns 160e, and the sixth epitaxial patterns 160f, may be configured to have the same potential. For example, as illustrated in FIG. 6, the first epitaxial patterns 160a, the second epitaxial patterns 160b, the fifth epitaxial patterns 160e, and the sixth epitaxial patterns 160f may be electrically connected to one another through the second wires 320. As a result, the same voltage level may be applied to the n-type epitaxial patterns (e.g., the first epitaxial patterns 160a, the second epitaxial patterns 160b, the fifth epitaxial patterns 160e, and the sixth epitaxial patterns 160f). Though not shown in the drawings, the second wires 320 may be formed to extend in the second direction Y.

In some embodiments, the n-type epitaxial patterns (e.g., the first epitaxial patterns 160a, the second epitaxial patterns 160b, the fifth epitaxial patterns 160e, and the sixth epitaxial patterns 160f) may be connected to the substrate 100 (or the first fin pattern 110) to form diodes. For example, the substrate 100 of the first region I may include a well region (hereinafter referred to as the p-well region) containing p-type impurities. Each of the n-type epitaxial patterns (e.g., the first epitaxial patterns 160a, the second epitaxial patterns 160b, the fifth epitaxial patterns 160e, and the sixth epitaxial patterns 160f) may be connected to the p-well region to form PN diodes. For example, the p-well region may be formed within the substrate 100. In some embodiments, when the diodes are operating, there may be substantially no current flow through the Si patterns, which include the first bridge patterns 111 through 114, on the first region I.

The second source/drain contacts 280 may be connected to at least some of the ninth epitaxial patterns 260a through sixteenth epitaxial patterns 260h. For example, the second source/drain contacts 280 may contact the upper portions of at least some of the ninth epitaxial patterns 260a through sixteenth epitaxial patterns 260h through the interlayer insulating film 190.

In some embodiments, at least a set of the ninth through sixteenth active patterns A21 through A28 may be provided as the channel regions of NFETs or PFETs. When the NFETs or PFETs are operating, there may be substantial current flow through a corresponding set of the Si patterns, which include the second bridge patterns 211 through 214, on the second region II.

In some embodiments, each of the ninth epitaxial patterns 260a through sixteenth epitaxial patterns 260h may have different potentials on both sides of the second gate structures G2. For example, as illustrated in FIG. 3, ninth epitaxial patterns 260a on first sides of the second gate structures G2 may be configured to receive a first voltage level V1, and ninth epitaxial patterns 260a on second sides of the second gate structures G2 may be configured to receive a second voltage level V2, different from the first voltage level V1.

On the first region I, at least a selected one of the active patterns (e.g., the first, second, fifth, and sixth active patterns A11, A12, A15, and A16), may be spaced apart from another by a second pitch, which is n times (where n is a natural number greater than or equal to 2) the first pitch FP. For example, as illustrated in FIG. 1, the second active pattern A12 may be spaced apart from the fifth active pattern A15 by three times the first pitch FP. For example, the second pattern A12 may be spaced apart from the fifth active pattern A15 by 3FP. No active patterns having p-type conductivity may be disposed between the second and fifth active patterns A12 and A15. For example, no Si patterns having p-type conductivity may be disposed between the second and fifth active patterns A12 and A15. For example, the n-type epitaxial patterns (such as the first epitaxial patterns 160a, the second epitaxial patterns 160b, the fifth epitaxial patterns 160e, and the sixth epitaxial patterns 160f) may not be disposed between the second and fifth active patterns A12 and A15.

In some embodiments, on the first region I, the areas between the second and fifth active patterns A12 and A15 may be provided as dummy regions.

As used herein, the term “dummy” is used to refer to a component that has the same or similar structure and shape as other components but does not have a substantial function (e.g., to convey information). The “dummy” element may only exist as a pattern in the device. In some instances, a “dummy” element may be electrically floated, or may be connected to various voltage sources but otherwise not provide the same functionality of the non-dummy element it represents.

In some embodiments, at least some of the n-type active patterns (e.g., the third, fourth, seventh, and eighth active patterns A13, A14, A17, and A18) may be disposed between the p-type active patterns (e.g., the second and fifth active patterns A12 and A15) which are spaced apart from each other by the second pitch. For example, as illustrated in FIG. 1, the third and fourth active patterns A13 and A14 may be disposed between the second and fifth active patterns A12 and A15.

In the dummy regions, dummy elements may be disposed. For example, the n-type active patterns A13, A13, A17 and A18 may be dummy elements, and/or the epitaxial patterns 160c, 160d, 160g and 160h may be dummy elements.

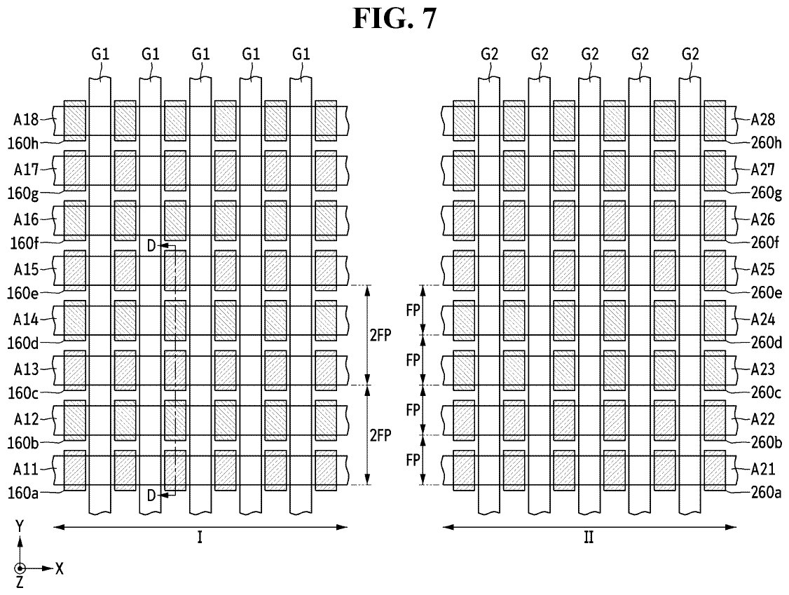

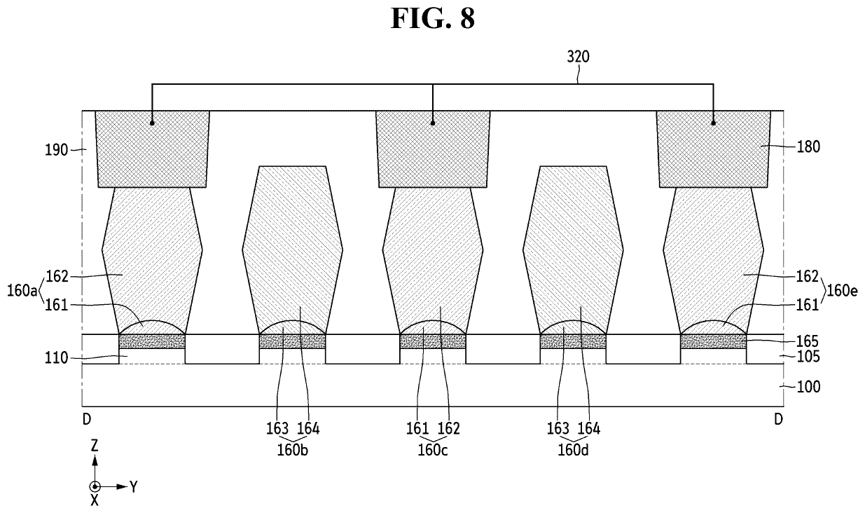

FIG. 7 is an example layout view for explaining a semiconductor device according to some embodiments. FIG. 8 is a cross-sectional view taken along line D-D of FIG. 7.

Throughout the specification, like features and elements have been identified by the same or similar reference numerals and/or letters. In describing each embodiment, previously discussed content may be briefly explained or omitted for conciseness. For example, in the description in conjunction with FIGS. 7 and 8, content that overlaps with what has been described above with reference to FIGS. 1 through 6 may be briefly explained or omitted.

Referring to FIGS. 7 and 8, first epitaxial patterns 160a, third epitaxial patterns 160c, fifth epitaxial patterns 160e, and seventh epitaxial patterns 160g may each have a second conductivity type (e.g., n-type), and second epitaxial patterns 160b, fourth epitaxial patterns 160d, sixth epitaxial patterns 160f, and eighth epitaxial patterns 160h may each have a first conductivity type (e.g., p-type).

For example, the first epitaxial patterns 160a, the third epitaxial patterns 160c, the fifth epitaxial patterns 160e, and the seventh epitaxial patterns 160g may include n-type impurities (e.g., P, Sb, or As) and/or impurities to prevent the diffusion of n-type impurities. In some embodiments, first, third, fifth, and seventh active patterns A11, A13, A15, and A17 may be provided as the channel regions of NFETs.

For example, the second epitaxial patterns 160b, the fifth epitaxial patterns 160e, and the sixth epitaxial patterns 160f may include p-type impurities (e.g., B, In, Ga, or Al) and/or impurities to prevent the diffusion of p-type impurities. In some embodiments, the second, fourth, sixth, and eighth active patterns A12, A14, A16, and A18 may be provided as the channel regions of PFETs.

On the first region I, at least some of the active patterns of p-type (e.g., the first, third, fifth, and seventh active patterns A11, A13, A15, and A17) may be spaced apart from each other by a second pitch 2FP. For example, as illustrated in FIG. 7, the first and third active patterns A11 and A13 may be spaced apart from each other by twice a first pitch FP, i.e., 2FP, and the third and fifth active patterns A13 and A15 may also be spaced apart from each other by twice the first pitch FP, i.e., 2FP. No p-type active patterns may be disposed between the first and third active patterns A11 and A13 and between the third and fifth active patterns A13 and A15. For example, the n-type epitaxial may not be disposed between the first and third active patterns A11 and A13.

In some embodiments, at least some of the n-type active patterns (e.g., the second, fourth, sixth, and eighth active patterns A12, A14, A16, and A18) may be disposed between each adjacent pair of the p-type active patterns (e.g., the first, third, fifth, and seventh active patterns A11, A13, A15, and A17) that are spaced apart from each other by the second pitch 2FP. For example, as illustrated in FIG. 7, the second active pattern A12 may be disposed between the first and third active patterns A11 and A13, and the fourth active pattern A14 may be disposed between the third and fifth active patterns A13 and A15.

In FIGS. 7 and 8, the configuration of the semiconductor device on the second region II may be the same as what has been described above with reference to FIGS. 1 through 6.

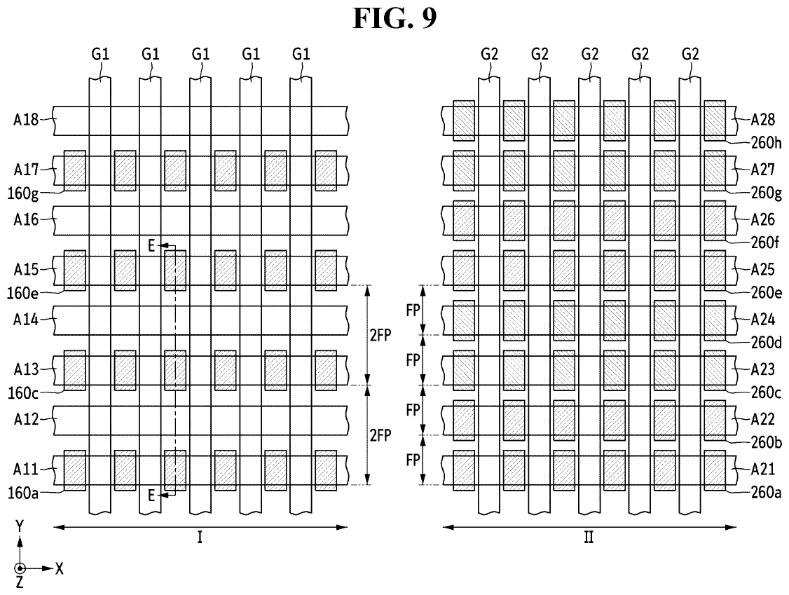

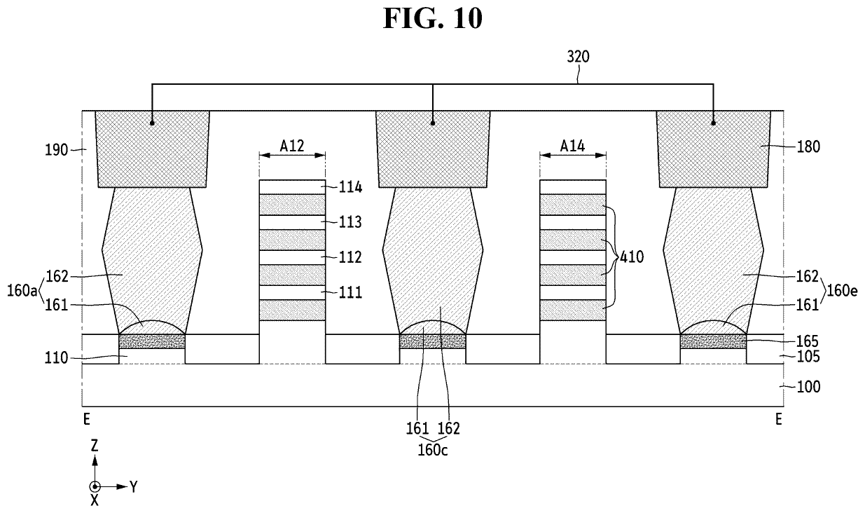

FIG. 9 is an example layout view for explaining a semiconductor device according to some embodiments. FIG. 10 is a cross-sectional view taken along line E-E of FIG. 9. For convenience of explanation, content that overlaps with what has been described above with reference to FIGS. 1 through 8 may be briefly explained or omitted.

Referring to FIGS. 9 and 10, on the first region I, no p-type epitaxial patterns are formed between each adjacent pair of p-type active patterns (e.g., first, third, fifth, and seventh active patterns A11, A13, A15, and A17) that are spaced apart from each other by a second pitch 2FP.

For example, the p-type epitaxial patterns (such as, in FIGS. 7 and 8, the second epitaxial patterns 160b, fourth epitaxial patterns 160d, sixth epitaxial patterns 160f, and eighth epitaxial patterns 160h) may not be formed on the first region I. For example, no epitaxial patterns may be formed between a pair of the active patterns A11 and A13, between a pair of the active patterns A13 and A15, and between a pair of the active patterns A15 and A17 on the first region I.

In some embodiments, sacrificial patterns 410 may be formed between the NFET active patterns (e.g., the first, third, fifth, and seventh active patterns A11, A13, A15, and A17). The sacrificial patterns 410 may be alternately stacked with first bridge patterns (111 through 114). The sacrificial patterns 410 may include a material with an etch selectivity with respect to the first bridge patterns (111 through 114). For example, the first bridge patterns (111 through 114) may be Si patterns, and the sacrificial patterns 410 may be SiGe patterns.

In FIGS. 9 and 10, the configuration of the semiconductor device on the second region II may be the same as what has been described above with reference to FIGS. 1 through 6.

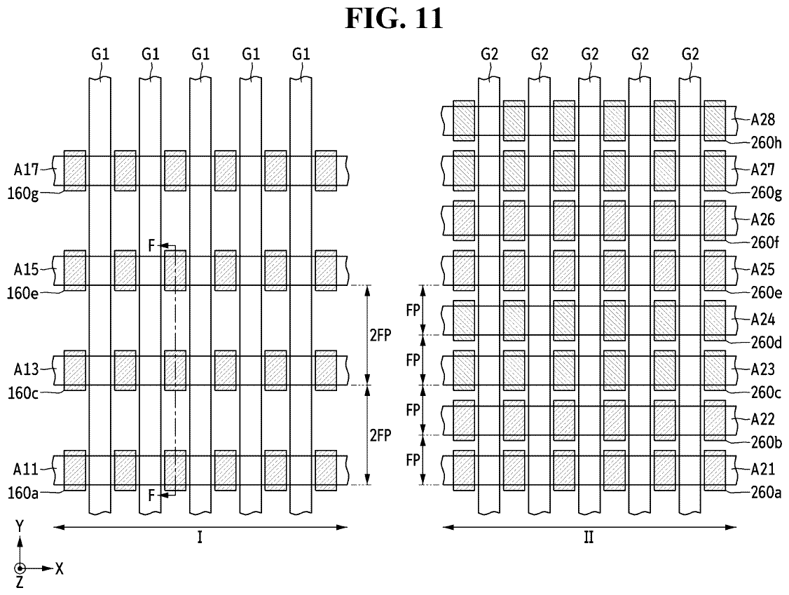

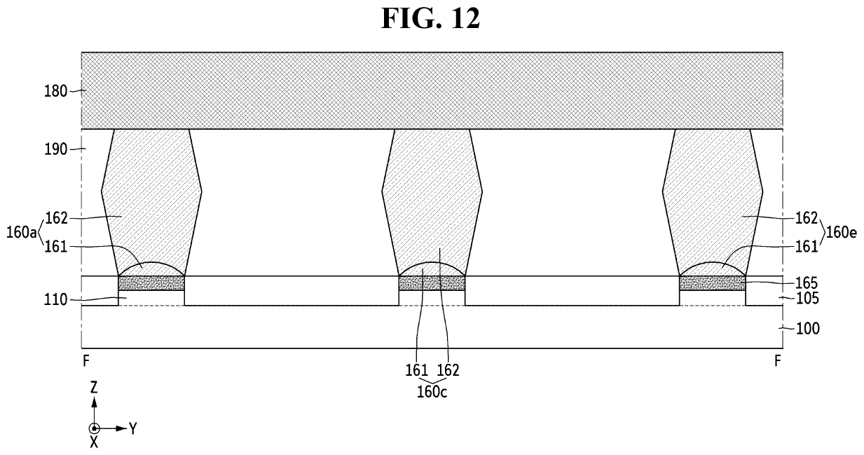

FIG. 11 is an example layout view for explaining a semiconductor device according to some embodiments. FIG. 12 is a cross-sectional view taken along line F-F of FIG. 11. For convenience of explanation, content that overlaps with what has been described above with reference to FIGS. 1 through 10 may be briefly explained or omitted.

Referring to FIGS. 11 and 12, on the first region I, no active patterns are formed between each adjacent pair of p-type active patterns (e.g., first, third, fifth, and seventh active patterns A11, A13, A15, and A17) that are spaced apart from each other by a second pitch 2FP. In some embodiments, no epitaxial patterns are formed between each adjacent pair of p-type active patterns that are spaced apart from each other by a second pitch 2FP on the first region I.

For example, the second, fourth, sixth, and eighth active patterns A12, A14, A16, and A18 (which are described in FIGS. 9 and 10) may be formed on the first region I.

In some embodiments, a field insulating film 105 and an interlayer insulating film 190 may fill the areas between each adjacent pair of the p-type active patterns (e.g., the first, third, fifth, and seventh active patterns A11, A13, A15, and A17) that are spaced apart from each other by the second pitch FP2.

In FIGS. 11 and 12, the configuration of the semiconductor device on the second region II may be the same as what has been described above with reference to FIGS. 1 through 6.

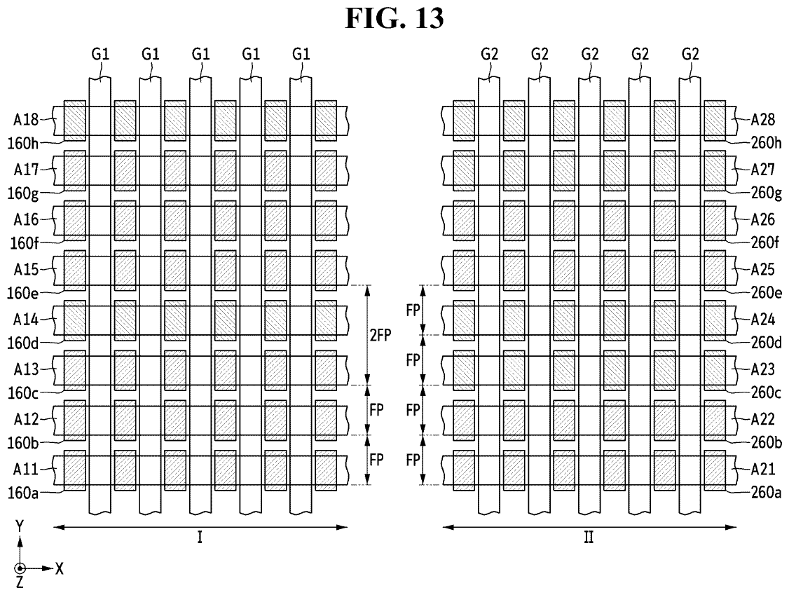

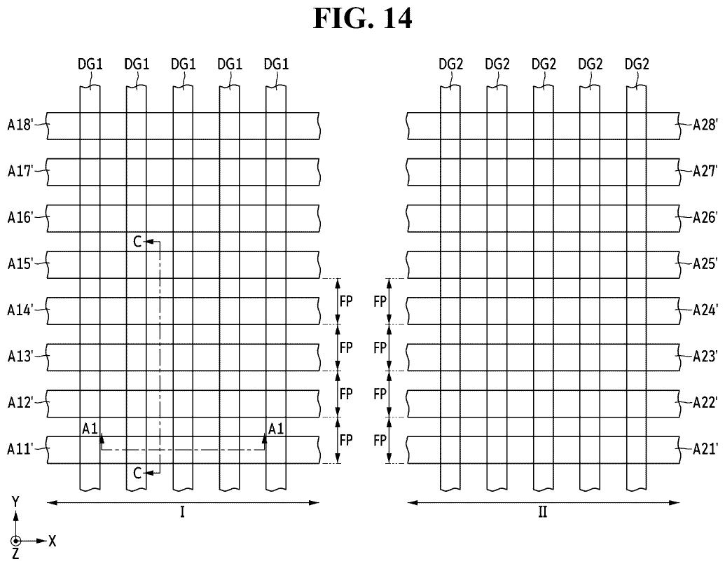

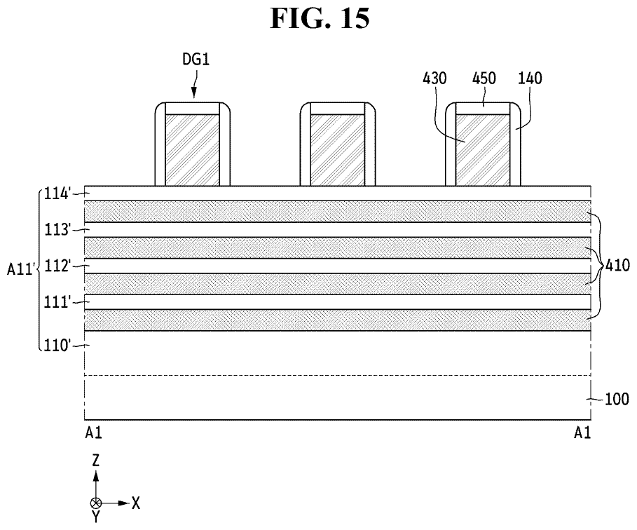

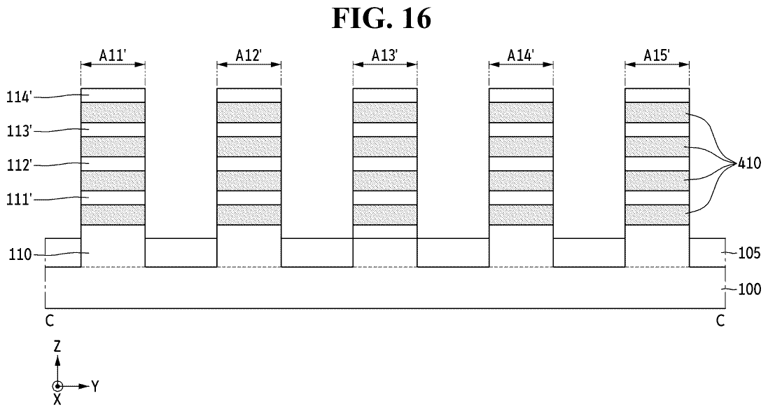

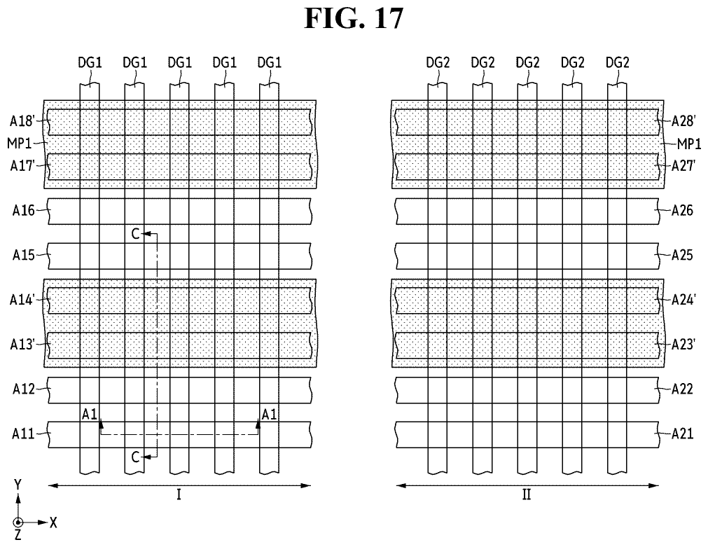

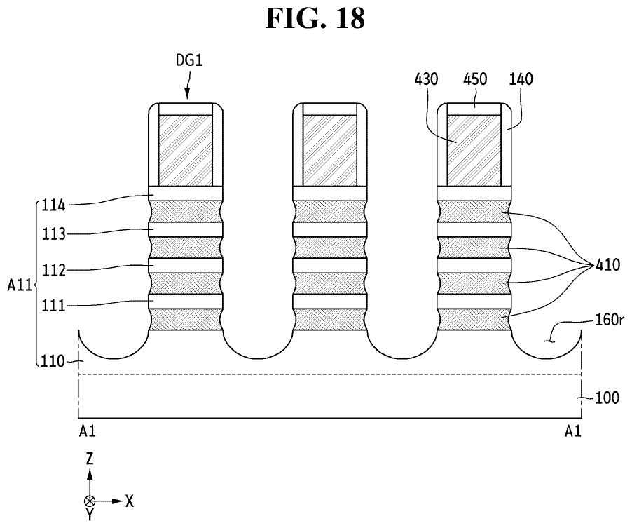

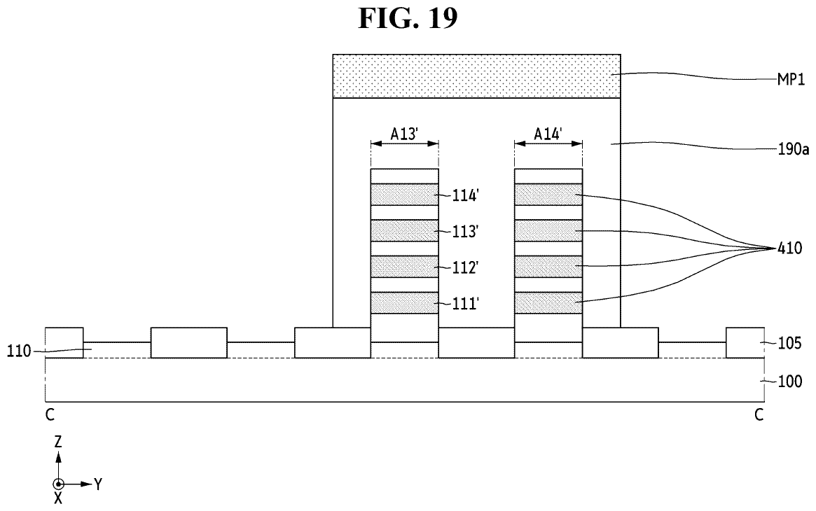

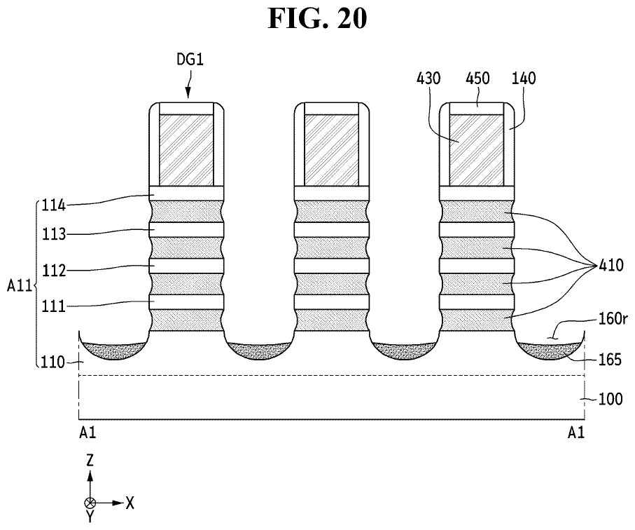

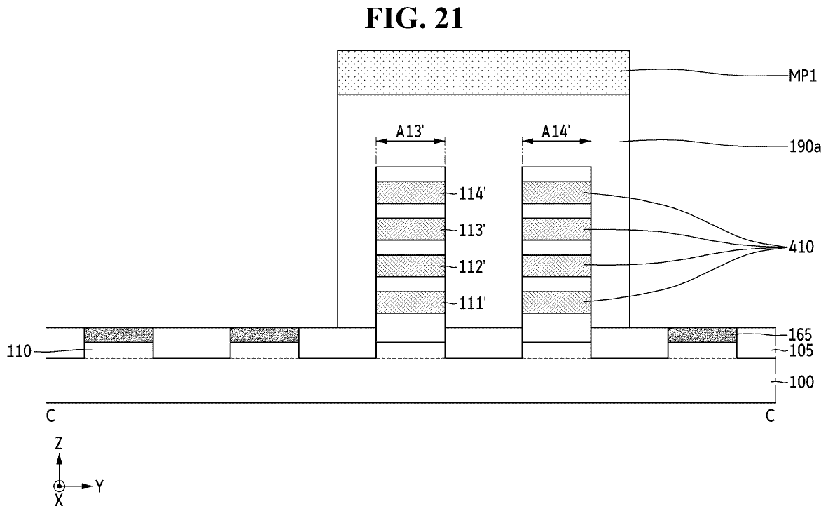

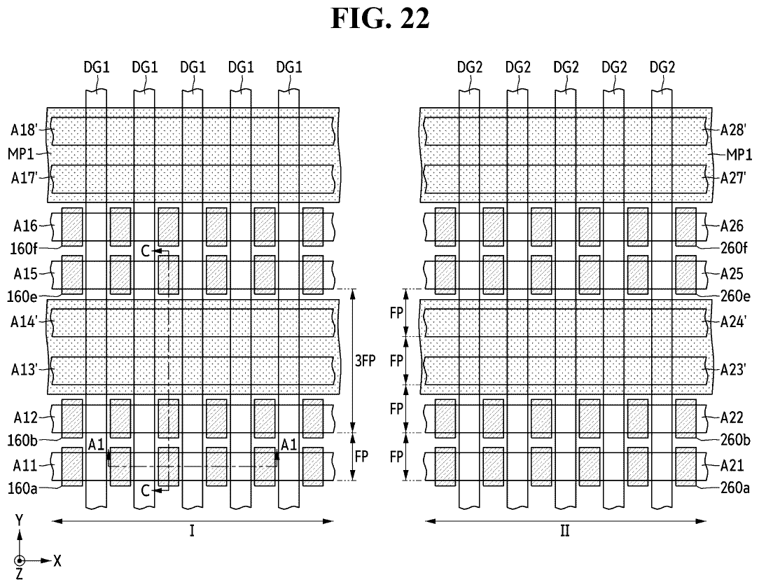

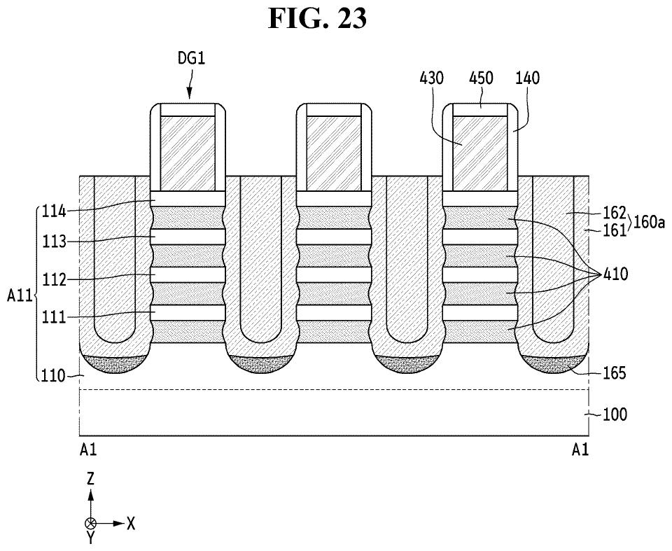

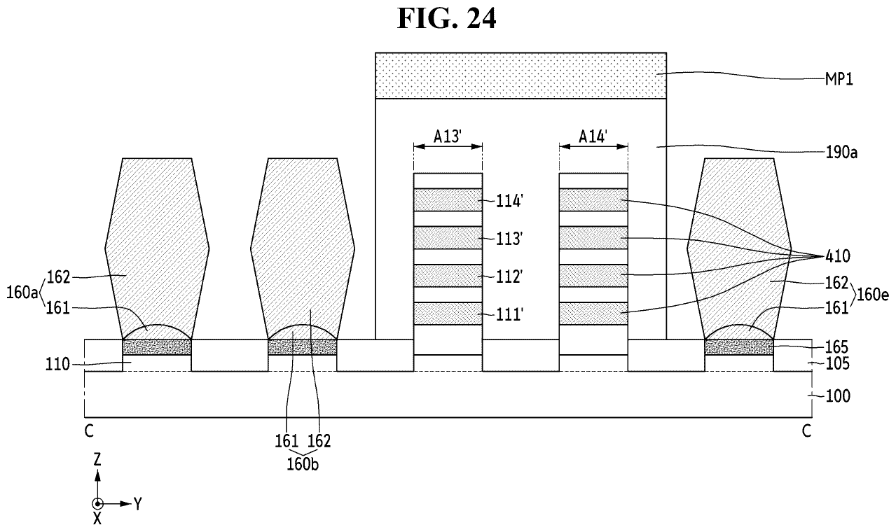

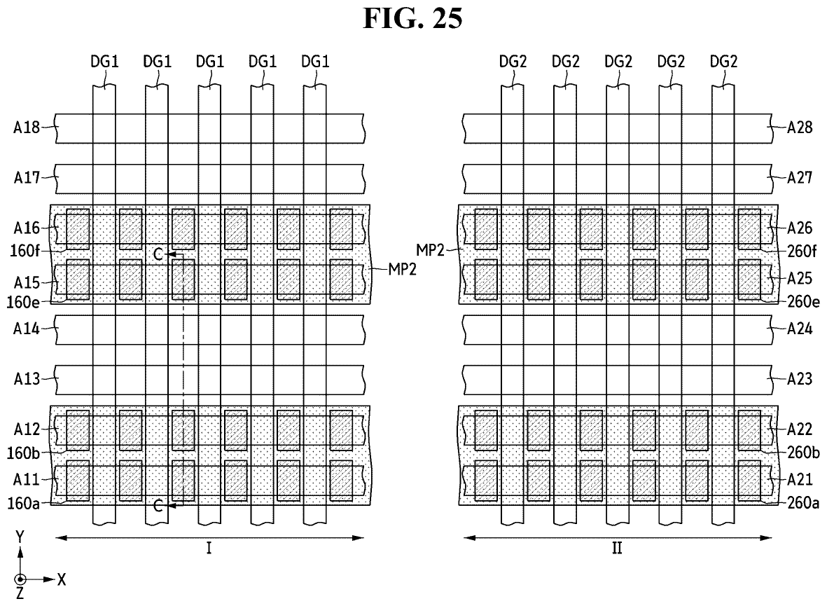

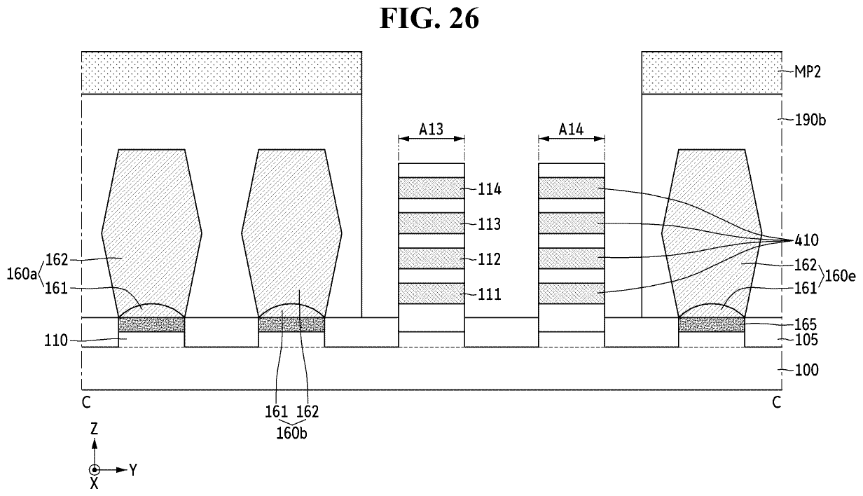

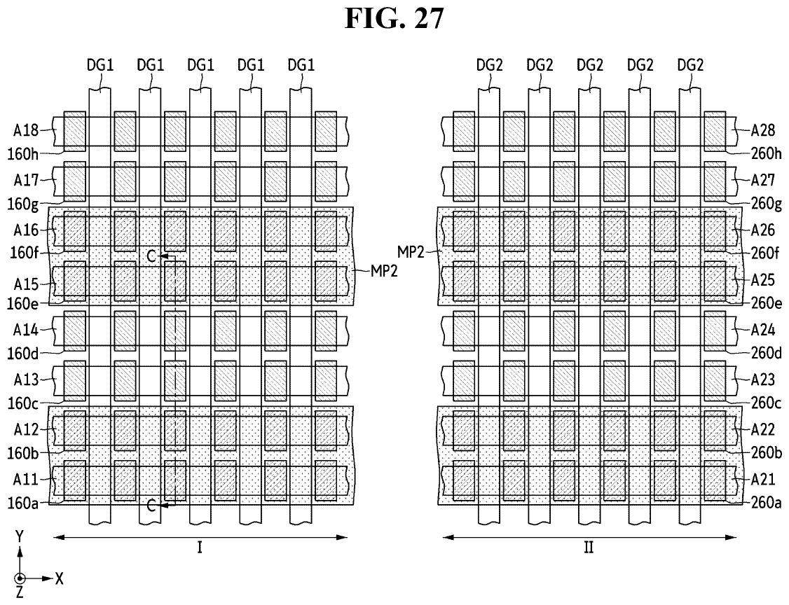

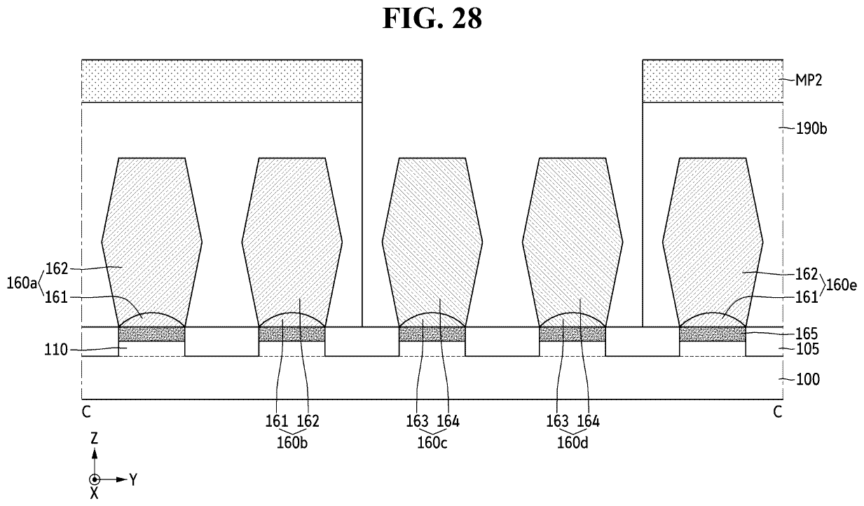

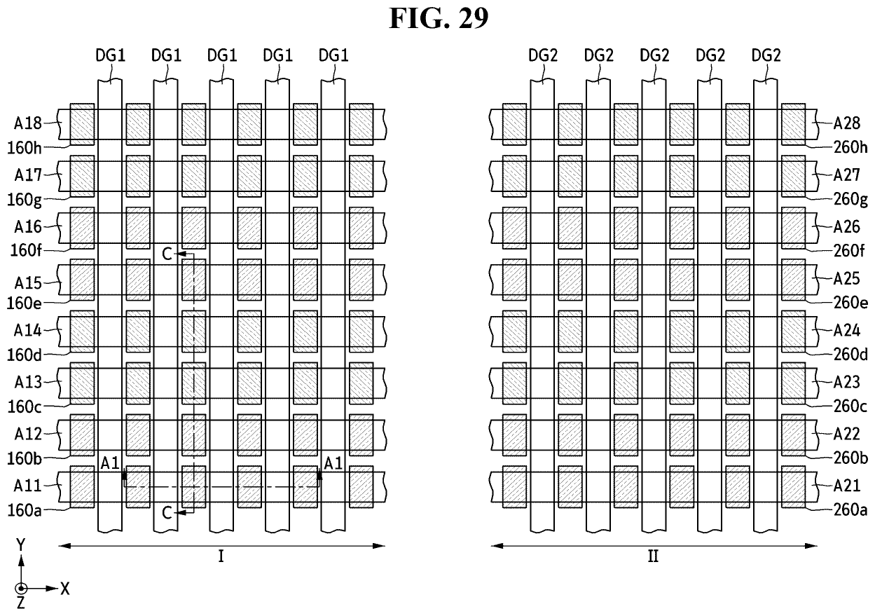

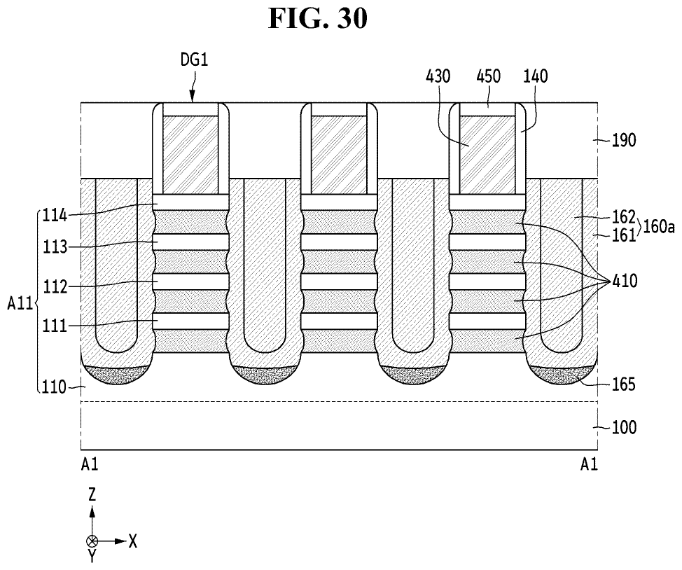

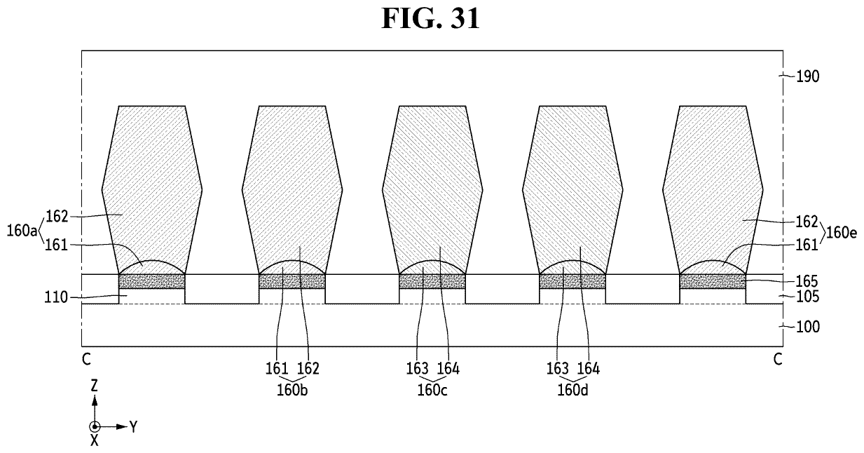

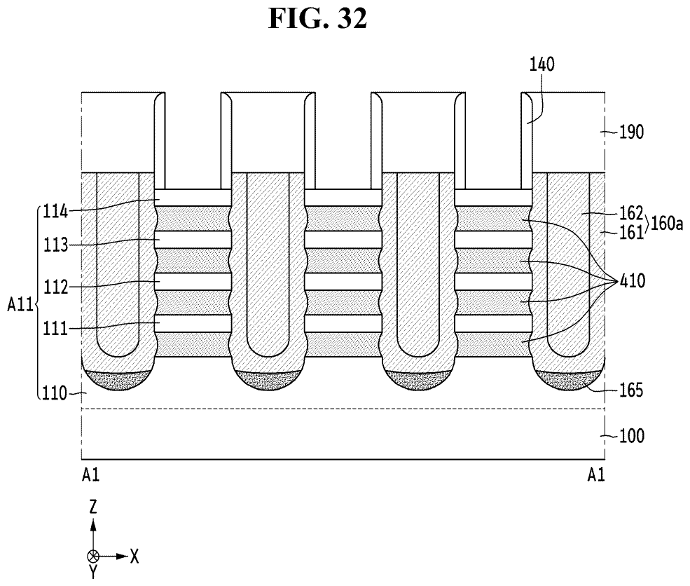

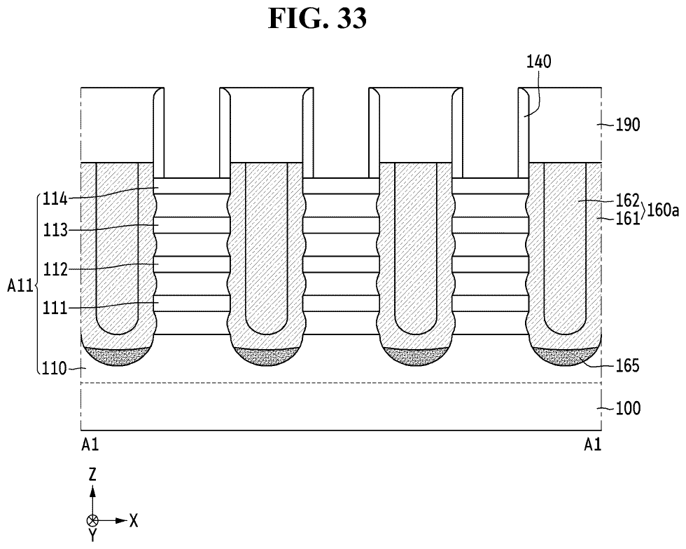

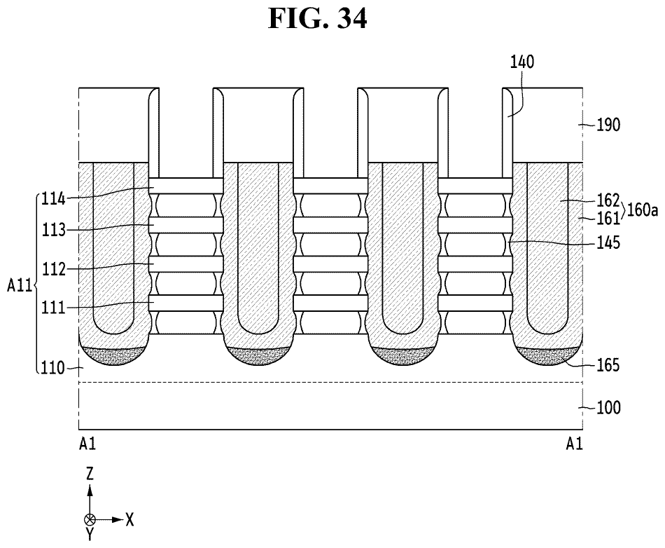

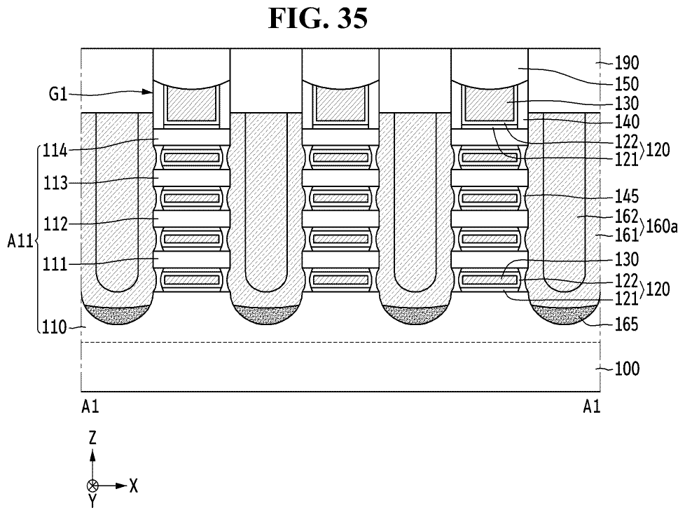

FIG. 13 is an example layout view for explaining a semiconductor device according to some embodiments. For convenience of explanation, content that overlaps with what has been described above with reference to FIGS. 1 through 12 may be briefly explained or omitted.

Referring to FIG. 13, first epitaxial patterns 160a, second epitaxial patterns 160b, third epitaxial patterns 160c, fifth epitaxial patterns 160e, sixth epitaxial patterns 160f, and seventh epitaxial patterns 160g may have a second conductivity type, and fourth epitaxial patterns 160d and eighth epitaxial patterns 160h may have a first conductivity type.

For example, the first epitaxial patterns 160a, second epitaxial patterns 160b, third epitaxial patterns 160c, fifth epitaxial patterns 160e, sixth epitaxial patterns 160f, and seventh epitaxial patterns 160g may include n-type impurities (e.g., P, Sb, or As) and/or impurities to prevent the diffusion of n-type impurities. In some embodiments, the first epitaxial patterns 160a, second epitaxial patterns 160b, third epitaxial patterns 160c, fifth epitaxial patterns 160e, sixth epitaxial patterns 160f, and seventh epitaxial patterns 160g may be provided as the channel regions of NFETs.

For example, the fourth epitaxial patterns 160d and the eighth epitaxial patterns 160h may include p-type impurities (e.g., B, In, Ga, or Al) and/or impurities to prevent the diffusion of p-type impurities. In some embodiments, fourth and eighth active patterns A14 and A18 may be provided as the channel regions of PFETs.

On a first region I, at least some of the active patterns having p-type conductivity (e.g., first through third and fifth through seventh active patterns A11 through A13 and A15 through A17) may be spaced apart from each other by a second pitch 2FP. For example, as illustrated in FIG. 7, the first and second active patterns A11 and A12 may be spaced apart from each other by a first pitch FP, the second and third active patterns A12 and A13 may be spaced apart from each other by the first pitch FP, and the third and fifth active patterns A13 and A15 may be spaced apart from each other by twice the first pitch FP, i.e., 2FP. No p-type active patterns may be disposed between the third and fifth active patterns A13 and A15.

In FIG. 13, the configuration of the semiconductor device on the second region II may be the same as what has been described above with reference to FIGS. 1 through 6.

In some embodiments of the present invention, the structures corresponding to the region I and the region II of each of the semiconductor devices described in reference to FIGS. 1 to 13 may act as a diode (or diodes) and a transistor (or transistors), respectively, in the integrated circuit of each of the semiconductor devices.

For example, the diode may be an ESD (electrostatic discharge) protection device. For example, the diode may be a PN diode coupled between an I/O pad and a power rail (VDD rail or VSS rail). The power rail and I/O pad may be conductive patterns formed in the semiconductor device. A set of the epitaxial patterns in the region I may act as one of anode or cathode of the diode, and the substrate (or well region formed within the substrate) may act as the other. A set of epitaxial patterns having a first conductivity type may be electrically connected to the same voltage level (a first voltage) as each other. In some embodiments, another set of epitaxial patterns having a second conductivity, which is different from the first conductivity type, may be dummy elements. For example, the n-type epitaxial patterns may be electrically connected to the VDD rail, and a p-type well region may be electrically connected to the I/O pad such that the n-type epitaxial patterns and the substrate (or p-type well region formed within the substrate) may be configured to constitute a diode and act a part of the integrated circuit (e.g., an ESD protection device).

In some embodiments, the diodes described in reference to FIGS. 1 to 13 may be a component in a power management circuit in a semiconductor device. For example, the power management circuit may be coupled to a power loss imminent capacitor. A conductive pattern may provide an electrical path to couple a charging circuit to the capacitor. Another conductive pattern may provide an electrical path such that a series current-limiting circuit and a diode (which has the same configuration as one of the diodes described in reference to FIGS. 1 to 13) are coupled in parallel with the current-limiting circuit. The diode with a cathode coupled to the charging circuit and an anode to couple to the capacitor. The diode may provide a current return path to return current from the capacitor to the charging circuit.

A method for manufacturing a semiconductor device according to some embodiments will hereinafter be described with reference to FIGS. 14 through 35.

Each of FIGS. 14 through 35 is either an example layout view or a cross-sectional view illustrating a process step for manufacturing a semiconductor device according to some embodiments. For convenience of explanation, content that overlaps with what has been described above with reference to FIGS. 1 through 13 may be briefly explained or omitted.

FIG. 15 is a cross-sectional view taken along line A1-A1 of FIG. 14, FIG. 16 is a cross-sectional view taken along line C-C of FIG. 14, FIG. 18 is a cross-sectional view taken along line A1-A1 of FIG. 17, FIG. 19 is a cross-sectional view taken along line C-C of FIG. 17, FIGS. 19, 20 and 21 are cross-sectional views taken along line C-C of FIG. 17, FIG. 23 is a cross-sectional view taken along line A1-A1 of FIG. 22, FIG. 24 is a cross-sectional view taken along line C-C of FIG. 22, FIG. 28 is a cross-sectional view taken along line C-C of FIG. 27, FIGS. 30, 32, 33, 34 and 35 are a cross-sectional views taken along line A1-A1 of FIG. 29, and FIG. 31 is a cross-sectional view taken along line C-C of FIG. 29.

Referring to FIGS. 14 through 16, first through eighth preliminary active patterns A11′ through A18′, ninth through sixteenth preliminary active patterns A21′ through A28′, first preliminary gate patterns DG1, and second preliminary gate patterns DG2 are formed on the substrate 100.

The first through eighth preliminary active patterns A11′ through A18′ may be formed on a first region I of a substrate 100. Each of the first through eighth preliminary active patterns A11′ through A18′ may include a plurality of first preliminary bridge patterns (111′ through 114′) that are spaced apart from each other and stacked. The first preliminary bridge patterns (111′ through 114′) may be alternately stacked with sacrificial patterns 410. The sacrificial patterns 410 may include a material with an etch selectivity with respect to the first preliminary bridge patterns (111′ through 114′). For example, the first bridge patterns (111 through 114) may be Si patterns, and the sacrificial patterns 410 may be SiGe patterns.

The ninth through sixteenth preliminary active patterns A21′ through A28′ may be formed on a second region II of the substrate 100. The ninth through sixteenth preliminary active patterns A21′ through A28′ may be similar to the first through eighth preliminary active patterns A11′ through A18′, and thus, a detailed description thereof may be omitted.

The first preliminary gate patterns DG1 may be formed on the first region I of the substrate 100. The first preliminary gate patterns DG1 may cross the first through eighth preliminary active patterns A11′ through A18′. The first preliminary gate patterns DG1 may include preliminary gate electrodes 430, preliminary gate mask patterns 450, and upper gate spacers 140. For example, a material film may be formed on the first through eighth preliminary active patterns A11′ through A18′. Thereafter, the preliminary gate mask patterns 450, which extend in a second direction Y, may be formed on the material film. Thereafter, a patterning process may be performed to pattern the material film using the preliminary gate mask patterns 450 as an etch mask. As a result, the preliminary gate electrodes 430 may be formed from the material film. The upper gate spacers 140 may extend along the sides of the preliminary gate electrodes 430.

The preliminary gate electrodes 430 may include a material with an etch selectivity with respect to the first through eighth preliminary active patterns A11′ through A18′. For example, the first through eighth preliminary active patterns A11′ through A18′ may be Si patterns, and the preliminary gate electrodes 430 may be polysilicon patterns.

The second preliminary gate patterns DG2 may be formed on the second region II of the substrate 100. The second preliminary gate patterns DG2 may be similar to the first preliminary gate patterns DG1, and thus, a detailed description thereof may be omitted.

Referring to FIGS. 17 through 19, a set of the preliminary active patterns may be covered by first mask patterns MP1. For example, the first, second, fifth, and sixth preliminary active patterns A11′, A12′, A15′, and A16′ and the ninth, tenth, thirteenth, and fourteenth preliminary active patterns A21′, A22′, A25′, and A26′ are selectively exposed.

For example, a first sacrificial insulating film 190a covering the first through eighth preliminary active patterns A11′ through A18′ and the ninth through sixteenth preliminary active patterns A21′ through A28′ may be formed. Thereafter, first mask patterns MP1 overlapping with the third, fourth, seventh, and eighth preliminary active patterns A13′, A14′, A17′, and A18′ and the eleventh, twelfth, fifteenth, and sixteenth active preliminary patterns A23′, A24′, A27′, and A28′ may be formed on the first sacrificial insulating film 190a. Thereafter, a patterning process may be performed to pattern the first sacrificial insulating film 190a using the first mask patterns MP1 as an etch mask. As a result of the patterning process, a first sacrificial insulating film 190a covering the third, fourth, seventh, and eighth preliminary active patterns A13′, A14′, A17′, and A18′ and the eleventh, twelfth, fifteenth, and sixteenth preliminary active patterns A23′, A24′, A27′, and A28′ may be formed.

Thereafter, a recess process may be performed on the first, second, fifth, and sixth active preliminary patterns A11′, A12′, A15′, and A16′ and the ninth, tenth, thirteenth, and fourteenth preliminary active patterns A21′, A22′, A25′, and A26′, which are exposed from the first sacrificial insulating film 190a. As a result, first recesses 160r may be formed within first fin pattern 110, and first bridge patterns (111 through 114) of first, second, fifth, and sixth active patterns A11, A12, A15, and A16 may be formed. Additionally, although not specifically illustrated in the drawings, second recesses 260r may be formed within second fin pattern 210, and second bridge patterns (211 through 214) of ninth, tenth, thirteenth, and fourteenth active patterns A21, A22, A25, and A26 may be formed.

Referring to FIGS. 20 and 21, a first insertion film 165 is formed within the first recesses 160r.

The first insertion film 165 may fill portions of the first recesses 160r. The first insertion film 165 may be formed through, for example, a deposition process and/or an epitaxial growth process, but the present invention is not limited thereto. Additionally, although not specifically illustrated in the drawings, a second insertion film 265 may be formed within the second recesses 260r.

Referring to FIGS. 22 through 24, first epitaxial patterns 160a, second epitaxial patterns 160b, fifth epitaxial patterns 160e, and sixth epitaxial patterns 160f, and ninth epitaxial patterns 260a, tenth epitaxial patterns 260b, thirteenth epitaxial patterns 260e, and fourteenth epitaxial patterns 260f are formed.

The first epitaxial patterns 160a, the second epitaxial patterns 160b, the fifth epitaxial patterns 160e, and the sixth epitaxial patterns 160f may be formed on the first, second, fifth, and sixth active patterns A11, A12, A15, and A16, respectively. The ninth epitaxial patterns 260a, the tenth epitaxial patterns 260b, the thirteenth epitaxial patterns 260e, and the fourteenth epitaxial patterns 260f may be formed on the ninth, tenth, thirteenth, and fourteenth active patterns A21, A22, A25, and A26, respectively.

In some embodiments, the first epitaxial patterns 160a, the second epitaxial patterns 160b, the fifth epitaxial patterns 160e, and the sixth epitaxial patterns 160f, and the ninth epitaxial patterns 260a, the tenth epitaxial patterns 260b, the thirteenth epitaxial patterns 260e, and the fourteenth epitaxial patterns 260f may have a second conductivity type (e.g., n-type).

After the formation of the epitaxial patterns 160a, 160b, 160e, 160f, 260a, 260b, 260e and 260f, the first sacrificial insulating film 190a and the first mask pattern MP1 may be removed.

Referring to FIGS. 25 and 26, a set of the preliminary active patterns may be covered by first mask patterns MP2. For example, the third, fourth, seventh, and eighth preliminary active patterns A13′, A14′, A17′, and A18′, and the eleventh, twelfth, fifteenth, and sixteenth preliminary active patterns A23′, A24′, A27′, and A28′ are selectively exposed.

For example, a second sacrificial insulating film 190b may be formed to cover the preliminary active patterns A13′, A14′, A17′, A18′, A23′, A24′, A27′ and A28′, and to cover the active patterns A11, A12, A15, A16, A21, A22, A25 and A26. Thereafter, the second mask patterns MP2 overlapping with the first, second, fifth, and sixth active patterns A11, A12, A15, and A16 and the ninth, tenth, thirteenth, and fourteenth active patterns A21, A22, A25, and A26 may be formed on the second sacrificial insulating film 190b. Thereafter, a patterning process may be performed to pattern the second sacrificial insulating film 190b using the second mask pattern MP2 as an etch mask. As a result of the patterning process, a second sacrificial insulating film 190covering the first, second, fifth, and sixth active patterns A11, A12, A15, A16 and the ninth, tenth, thirteenth, and fourteenth active patterns A21, A22, A25, and A26 may be formed.

Referring to FIGS. 27 and 28, third epitaxial patterns 160c, fourth epitaxial patterns 160d, seventh epitaxial patterns 160g, and eighth epitaxial patterns 160h, and eleventh epitaxial patterns 260c, twelfth epitaxial patterns 260d, fifteenth epitaxial patterns 260g, and sixteenth epitaxial patterns 260h are formed.

The third epitaxial patterns 160c, the fourth epitaxial patterns 160d, the seventh epitaxial patterns 160g, and the eighth epitaxial patterns 160h may be formed on the third, fourth, seventh, and eighth active patterns A13, A14, A17, and A18, respectively. The eleventh epitaxial patterns 260c, the twelfth epitaxial patterns 260d, the fifteenth epitaxial patterns 260g, and the sixteenth epitaxial patterns 260h may be formed on the eleventh, twelfth, fifteenth, and sixteenth active patterns A23, A24, A27, and A28, respectively.

In some embodiments, the third epitaxial patterns 160c, the fourth epitaxial patterns 160d, the seventh epitaxial patterns 160g, and the eighth epitaxial patterns 160h, and the eleventh epitaxial patterns 260c, the twelfth epitaxial patterns 260d, the fifteenth epitaxial patterns 260g, and the sixteenth epitaxial patterns 260h may have a first conductivity type (e.g., p-type).

After the formation of the epitaxial patterns 160c, 160d, 160g, 160h, 260c, 260d, 260g and 260h, the second sacrificial insulating film 190b and the second mask pattern MP2 may be removed.

Referring to FIGS. 29 through 31, an interlayer insulating film 190 is formed.

An interlayer insulating film 190 may be formed to fill the spaces on the outer sides of the first preliminary gate patterns DG1 and the second preliminary gate patterns DG2. The interlayer insulating film 190 may cover the first epitaxial patterns 160a through the eighth epitaxial patterns 160h and the ninth epitaxial patterns 260a through the sixteenth epitaxial patterns 260h.

Referring to FIG. 32, the preliminary gate electrodes 430 are removed.

The preliminary gate electrodes 430 may be selectively removed with respect to the first bridge patterns (111 through 114) and the second bridge patterns (211 through 214).

Referring to FIG. 33, the sacrificial patterns 410 are removed.

The sacrificial patterns 410 may be selectively removed with respect to the first bridge patterns (111 through 114) and the second bridge patterns (211 through 214).

Referring to FIG. 34, inner spacers 145 are formed.

For example, a spacer film may be formed in the areas from which the sacrificial patterns 410 have been removed. Thereafter, a recess process may be performed on the spacer film, thereby partially removing the spacer film. As a result, the inner spacers 145 may be formed in the areas between the first bridge patterns (111 through 114) and the areas between the second bridge patterns (211 through 214).

Referring to FIG. 35, a gate dielectric film 120, gate electrodes 130, and a gate capping film 150 are formed.

The gate dielectric film 120 and the gate electrodes 130 may fill the areas from which the preliminary gate electrode 430 and the sacrificial patterns 410 have been removed. The gate capping film 150 may cover the upper surfaces of the gate electrodes 130. As a result, first gate structures G1 that replace the first preliminary gate patterns DG1 may be formed, and second gate structure G2 that replace the second preliminary gate patterns DG2 may be formed.

Thereafter, referring again to FIGS. 1 through 6, first source/drain contacts 180 and second source/drain contacts 280 are formed. Through this, the semiconductor device described above with reference to FIGS. 1 through 6 can be manufactured.

In some embodiments, in the region I, active patterns and/or epitaxial patterns may not be formed in at least a portion of the area which is covered by the first mask patterns MP1. Instead, dummy elements may be formed in the portion of the area which is covered by the first mask patterns MP1.

To implement a diode device, a semiconductor device including multi-bridge channels may be used. For example, PN diodes may be provided using a p-type substrate and n-type epitaxial patterns connected to the p-type substrate. However, during an etching process for forming the n-type epitaxial patterns, there is an issue in which recesses of excessive depth are formed due to the close arrangement of multiple n-type epitaxial patterns, causing leakage current.

On the contrary, in the semiconductor device and its manufacturing method according to some embodiments of the invention, due to a dummy region (or p-type epitaxial patterns) between multiple n-type epitaxial patterns, the depth of recesses can be controlled by utilizing a loading effect. Specifically, as described above, at least some of the active patterns of p-type (e.g., first, second, fifth, and sixth active patterns A11, A12, A15, and A16) may be spaced apart from each other by a second pitch, which is n times a first pitch FP (where n is a natural number of 2 or greater). For example, the second and fifth active patterns A12 and A15 may be spaced apart from each other by three times the first pitch FP, i.e., 3FP, and the area between the second and fifth active patterns A12 and A15 may be provided as the dummy region. Additionally, during the formation of the n-type epitaxial patterns (e.g., first epitaxial patterns 160a, second epitaxial patterns 160b, fifth epitaxial patterns 160e, and sixth epitaxial patterns 160f), the dummy region may be closed (covered) by first mask patterns MP1. As a result, during the formation of first recesses 160r, the exposed areas of p-type active patterns (e.g., the first, second, fifth, and sixth active patterns A11, A12, A15, and A16) may be reduced, and the depth of the first recesses 160r may be controlled. Through this, a semiconductor device with improved yield and performance can be provided.

Although embodiments of the present disclosure have been described with reference to the accompanying drawings, the present invention is not limited to the above embodiments but may be implemented in various different forms. A person skilled in the art may appreciate that the disclosure may be modified without departing from the technical spirit or essential characteristics of the present invention. Therefore, it should be appreciated that the embodiments as described above are not restrictive but illustrative in all respects.

What is claimed is:

1. A semiconductor device comprising:
a substrate including a first region and a second region and having a first conductivity type;
first and second active patterns spaced apart from each other by a first pitch, on the first region;
a first gate pattern intersecting the first and second active patterns, the first gate pattern having a first side and a second side facing away from each other;
first epitaxial patterns each having a second conductivity type, different from the first conductivity type, on the first and second sides of the first gate pattern on each of the first and second active patterns, the first epitaxial patterns configured to receive the same voltage level as each other;
third and fourth active patterns spaced apart from each other by a second pitch, on the second region;
a second gate pattern intersecting the third and fourth active patterns, the second gate pattern having a third side and a fourth side facing away from each other; and
second epitaxial patterns each having the second conductivity type, on the third and fourth sides of the second gate pattern on each of the third and fourth active patterns,
wherein:
the first pitch is n times greater than the second pitch,
n is a natural number of 2 or greater, and
no epitaxial pattern having the second conductivity type is disposed between the first and second active patterns.

2. The semiconductor device of claim 1, wherein each of the first, second, third, and fourth active patterns includes a plurality of channel patterns that are stacked and spaced apart from each other on the substrate.

3. The semiconductor device of claim 1, wherein:
first recesses are formed in each of the first active patterns, each of the first epitaxial patterns is disposed on a corresponding one of the first recesses,
second recesses are formed in each of the second active patterns, each of the second epitaxial patterns is disposed on a corresponding one of the second recesses,
the first recesses are disposed at the first and second sides of the first gate pattern and at the first region, and
the second recesses are disposed at the third and fourth sides of the second gate pattern and at the second region.

4. The semiconductor device of claim 3, wherein a difference between a depth of a selected one of the first recesses and a depth of a selected one of the second recesses is 10% or less with respect to the depth of the selected one of the second recesses.

5. The semiconductor device of claim 3, further comprising:
first insertion patterns, each of which filling a portion of a corresponding one of the first recesses and disposed between the substrate and a corresponding one of the first epitaxial patterns; and
second insertion patterns, each of which filling a portion of a corresponding one of the second recesses and disposed between the substrate and a corresponding one of the second epitaxial patterns.

6. The semiconductor device of claim 5, wherein each of the first and second insertion patterns includes at least one of an SiB film, an SiN film, or an undoped Si film.

7. The semiconductor device of claim 1, further comprising:
a fifth active pattern interposed between the first and second active patterns, on the first region.

8. The semiconductor device of claim 7, further comprising:
a third epitaxial pattern having the first conductivity type, the third epitaxial pattern being on the first and second sides of the first gate pattern and on the fifth active pattern.

9. The semiconductor device of claim 7, wherein the fifth active pattern is spaced apart from the first active pattern by the second pitch.

10. The semiconductor device of claim 1, further comprising:
fifth and sixth active patterns spaced apart from each other by the second pitch, on the second region; and
third epitaxial patterns each having the first conductivity type, on the third and fourth sides of the second gate pattern on each of the fifth and sixth active patterns.

11. A semiconductor device comprising:
a substrate having p-type conductivity;
a plurality of active patterns extending parallel to each other on the substrate;
a gate pattern intersecting the plurality of active patterns, the gate pattern having a first side and a second side facing away from each other;
epitaxial patterns on the first and second sides of the gate pattern, the epitaxial patterns configured to receive the same voltage level as each other and having n-type conductivity; and
insertion patterns each of which interposed between a corresponding one of the epitaxial patterns and the substrate,
wherein:
a plurality of recesses is formed in each of the plurality of active patterns,
each of the insertion patterns fills a portion of a corresponding one of the plurality of recesses,
the plurality of active patterns include first to third active patterns that are sequentially arranged,
the first and second active patterns are spaced apart from each other by a first pitch,
the second and third active patterns are spaced apart from each other by a second pitch,
the second pitch is n times greater than the first pitch,
n is a natural number of 2 or greater, and
no epitaxial pattern including n-type conductivity is disposed between the second and third active patterns.

12. The semiconductor device of claim 11, wherein each of the active patterns includes a plurality of channel patterns that are stacked and spaced apart from each other on the substrate.

13. The semiconductor device of claim 11, wherein:
each of the plurality of recesses are formed in an upper surface of a corresponding one of the plurality of active patterns, and
a depth of each of the plurality of the recesses is 60 nm to 75 nm from the upper surface of a corresponding one of the plurality of active patterns.

14. The semiconductor device of claim 11, wherein a thickness of a selected one of the insertion patterns is 1 nm to 10 nm in a direction perpendicular to an upper surface of the substrate.

15. The semiconductor device of claim 11, wherein each of the insertion patterns includes at least one of a SiB film, a SiN film, or an undoped Si film.

16. A semiconductor device comprising:
a substrate having p-type conductivity;
first to third active patterns on the substrate, the first to third active patterns each extending in a first direction and sequentially arranged along a second direction intersecting the first direction;
a gate pattern extending in the second direction on the first to third active patterns, the gate pattern having a first side and a second side facing away from each other;
first epitaxial patterns each connected to the substrate and each having n-type conductivity, on the first and second sides of the gate pattern on the first active pattern;
second epitaxial patterns each connected to the substrate and each having p-type conductivity, on the first and second sides of the gate pattern on the second active pattern; and
third epitaxial patterns each connected to the substrate and each having n-type conductivity, on the first and second sides of the gate pattern on the third active pattern,
wherein:
each of the first to third active patterns includes a plurality of channel patterns that are stacked and spaced apart from each other on the substrate, and
the first and third epitaxial patterns configured to receive the same voltage level as each other.

17. The semiconductor device of claim 16, wherein:
each of the first to third active patterns further includes a fin pattern that protrudes from an upper surface of the substrate and extends in the first direction,
the fin pattern includes recesses on the first and second sides of the gate pattern, and
each of the first, second and third epitaxial patterns is disposed on a corresponding one of the recesses.

18. The semiconductor device of claim 17, further comprising insertion patterns filling a portion of each of the recesses, the insertion patterns each located between the substrate and a corresponding one of the first, second and third epitaxial patterns.

19. The semiconductor device of claim 18, wherein each of the insertion patterns includes at least one of a SiB film, a SiN film, or an undoped Si film.

20. The semiconductor device of claim 16, wherein the first to third active patterns are adjacent to each other.
